(19) United States
(12) Patent Application Publication
(10) Pub. No.: US 2025/0062226 A1
(43) Pub. Date: Feb. 20, 2025

(54) THREE-DIMENSIONAL INTEGRATED CIRCUIT STACK

(71) Applicant: Taiwan Semiconductor Manufacturing Company, Ltd., Hsinchu (TW)

(72) Inventors: Ching-Ho CHIN, Taoyuan City (TW); Chung-Hao Tsai, Changhua County (TW); Chuei-Tang WANG, Taichung City (TW); Chen-Hua Yu, Hsinchu City (TW)

(73) Assignee: Taiwan Semiconductor Manufacturing Company, Ltd., Hsinchu (TW)

(21) Appl. No.: 18/450,358

(22) Filed: Aug. 15, 2023

(51) Int. Cl. H01L 23/528; H01L 23/522; H01L 27/06

(52) U.S. Cl. CPC H01L 23/5283; H01L 23/5226; H01L 27/0688

(57) ABSTRACT

A three-dimensional integrated circuit stack comprises a first integrated circuit structure, a second integrated circuit structure bonding to the first integrated circuit structure, and a redistribution structure. The first integrated circuit structure comprises a first semiconductor device, a first buffer structure, a first interconnect structure, a first conductive via, and a first through via. The first semiconductor device is located between the first buffer structure and the first interconnect structure. The first conductive via is extending through the first buffer structure and in contact with the first semiconductor device. The first through via is extending from the first buffer structure to the first interconnect structure. The redistribution structure is disposed on the first buffer structure, electrically connected to the first semiconductor device through the first conductive via, and electrically connected to the first interconnect structure through the first through via.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area. Three-dimensional integrated circuit (3DIC) is a technology that enables the vertical integration of multiple semiconductor dies or chips within a single package. This approach offers several advantages over traditional two-dimensional (2D) integrated circuits, including improved performance, reduced form factor, and increased functionality.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1R illustrate cross-sectional views of a method for fabricating a three-dimensional integrated circuit stack, according to various embodiments of the present disclosure.

FIG. 2 illustrates a cross-sectional view of a three-dimensional integrated circuit stack, in accordance with some alternative embodiments.

FIG. 3 illustrates a cross-sectional view of a three-dimensional integrated circuit stack, in accordance with some alternative embodiments.

FIG. 4 illustrates a cross-sectional view of a three-dimensional integrated circuit stack, in accordance with some alternative embodiments.

FIG. 5 illustrates a cross-sectional view of a three-dimensional integrated circuit stack, in accordance with some alternative embodiments.

FIG. 6 illustrates a cross-sectional view of a three-dimensional integrated circuit stack, in accordance with some alternative embodiments.

FIGS. 7A to 7G illustrate cross-sectional views of a method for fabricating a three-dimensional integrated circuit stack, according to various embodiments of the present disclosure.

FIGS. 8A to 8C illustrate cross-sectional views of a method for fabricating a three-dimensional integrated circuit stack, according to various embodiments of the present disclosure.

FIG. 9 illustrates a cross-sectional view of a three-dimensional integrated circuit stack, in accordance with some alternative embodiments.

FIG. 10 illustrates a top view of a three-dimensional integrated circuit stack, in accordance with some alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third” and the like, may be used herein for ease of description to describe similar or different element(s) or feature(s) as illustrated in the figures, and may be used interchangeably depending on the order of the presence or the contexts of the description.

A three-dimensional integrated circuit (3DIC) stack may include a plurality of IC dies bonded together. The IC dies may each comprise a semiconductor device and an interconnect structure having conductive wires and vias embedded in a dielectric structure. In some instances, a first IC die and a second IC die may be bonded to one another through hybrid bonding process that includes a metal-to-metal bonding and a dielectric-to-dielectric bonding. The first IC die and the second IC die may be bonded in a front-to-back (F2B) or in a back-to-back (B2B) orientation. In some embodiments, the pitch between the bonding pads used in the hybrid bonding process is less than 0.1 micrometers, thereby achieving improved bonding strength. In some embodiments, a 3DIC stack can also be referred to as a monolithic-like 3D package.

Generally, after stacking multiple dies together, the stack of the dies is connected to external components (such as a printed circuit board). In this situation, the distance between the upper-level die and the external components is greater than the distance between the lower-level die and the external components. This difference in distance can lead to voltage drop issues, such as IR drop. In some implementations of the present disclosure, the die includes through-via (e.g. feed through via) that extends from the front side of the die to the interconnect structure on a back side of the die. The through-via, in this configuration, has lower resistance values, which helps to reduce the issue of voltage drop.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

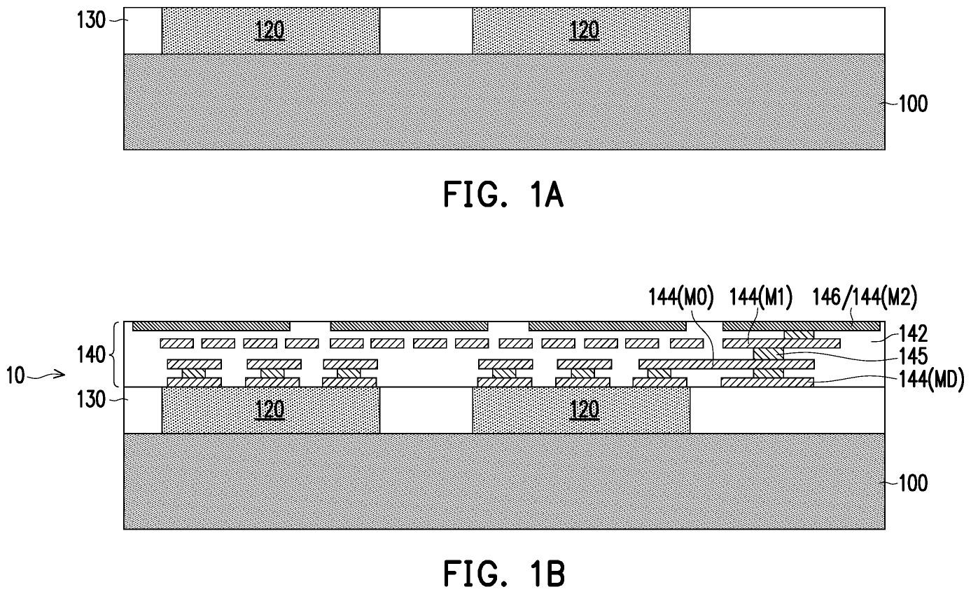

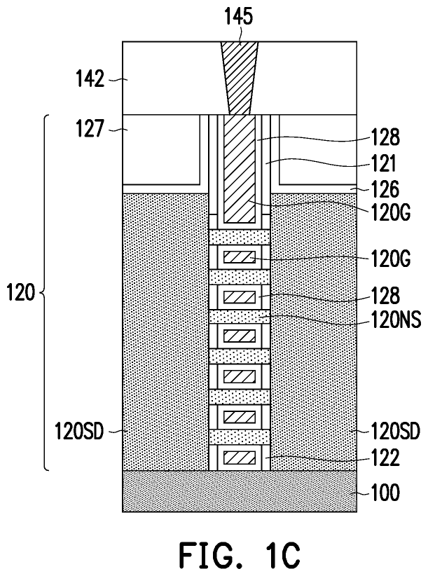

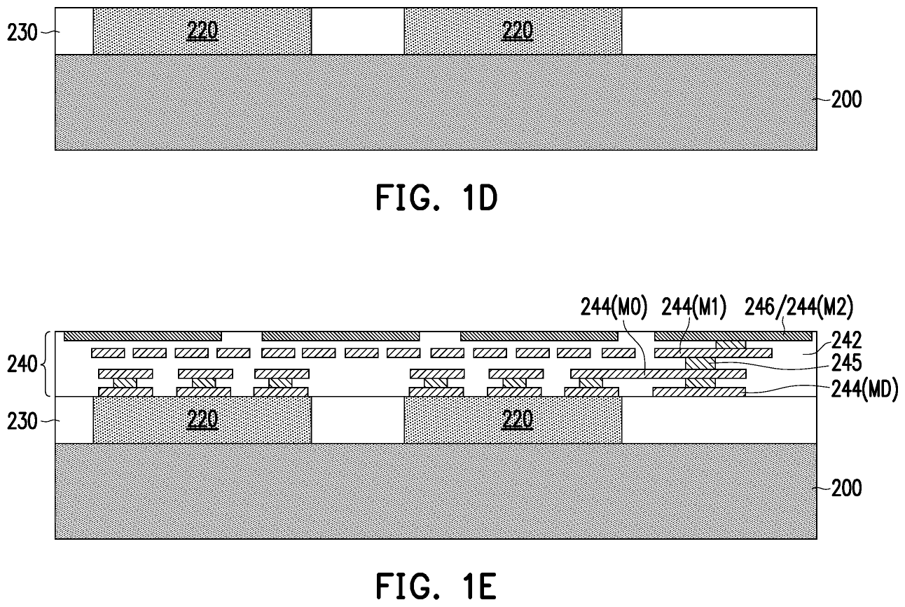

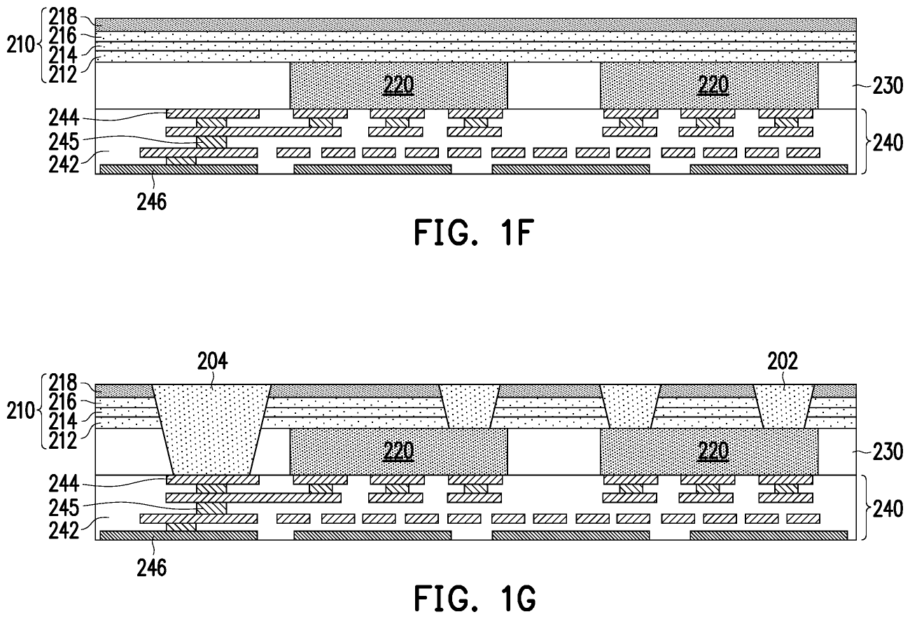

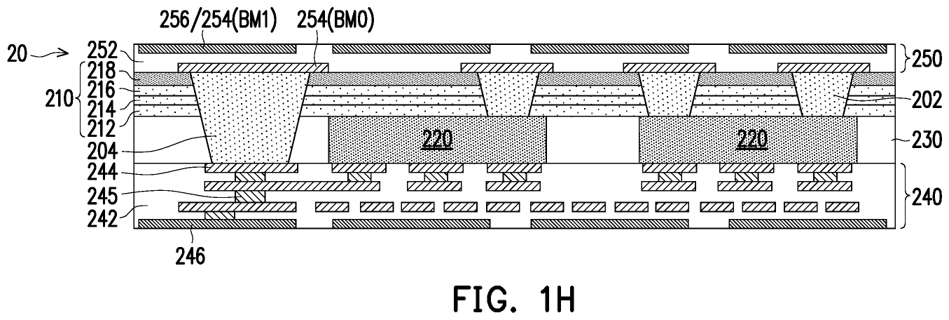

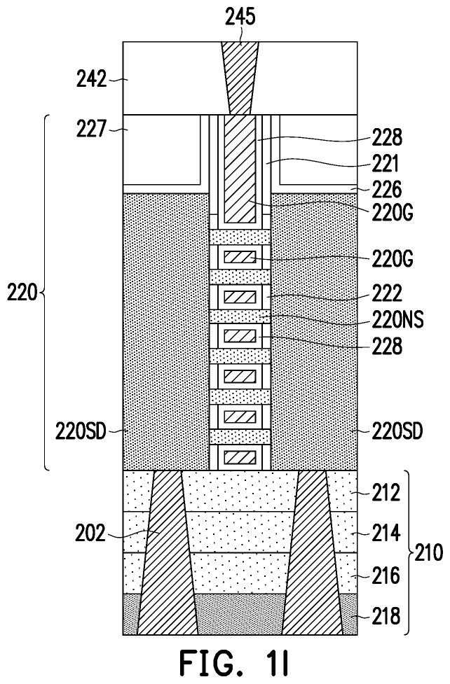

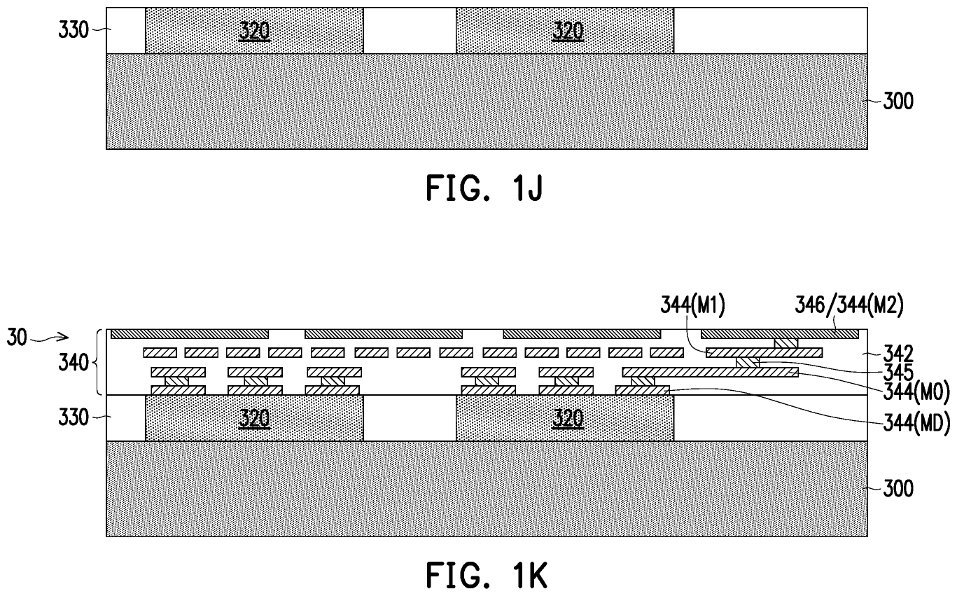

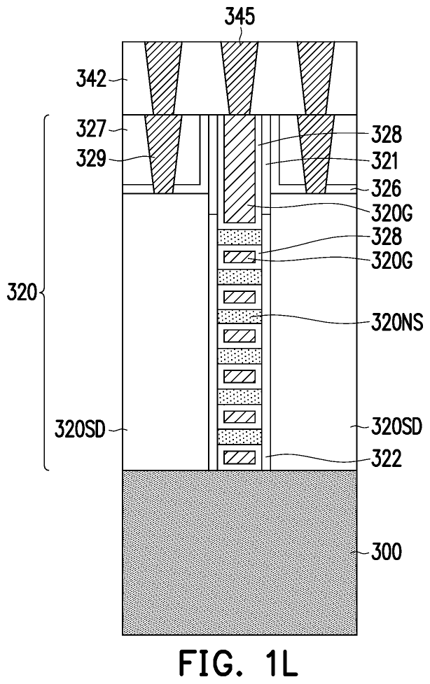

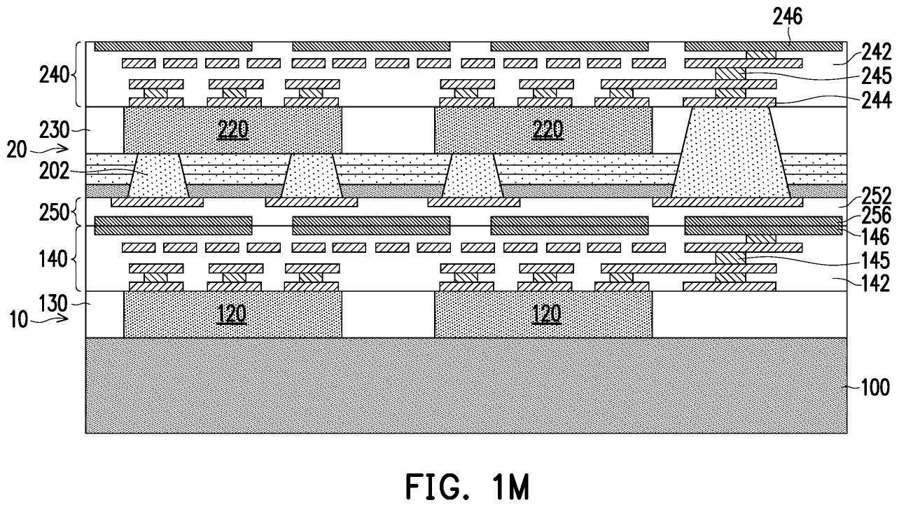

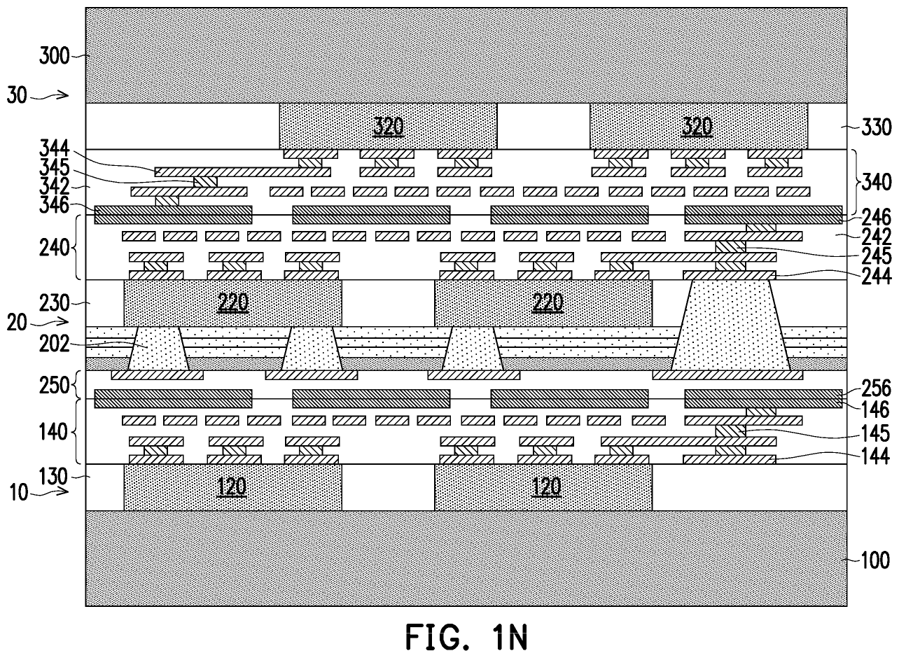

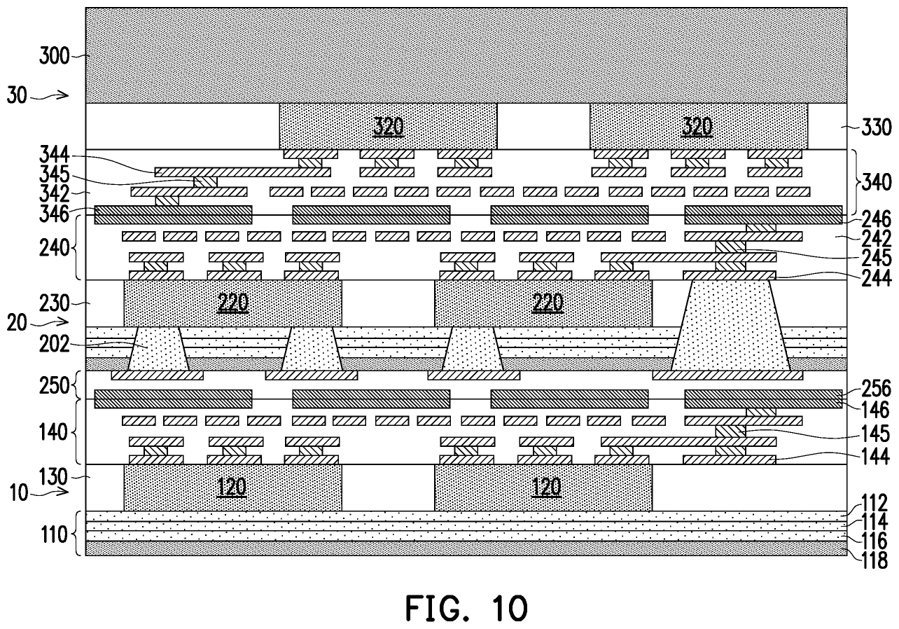

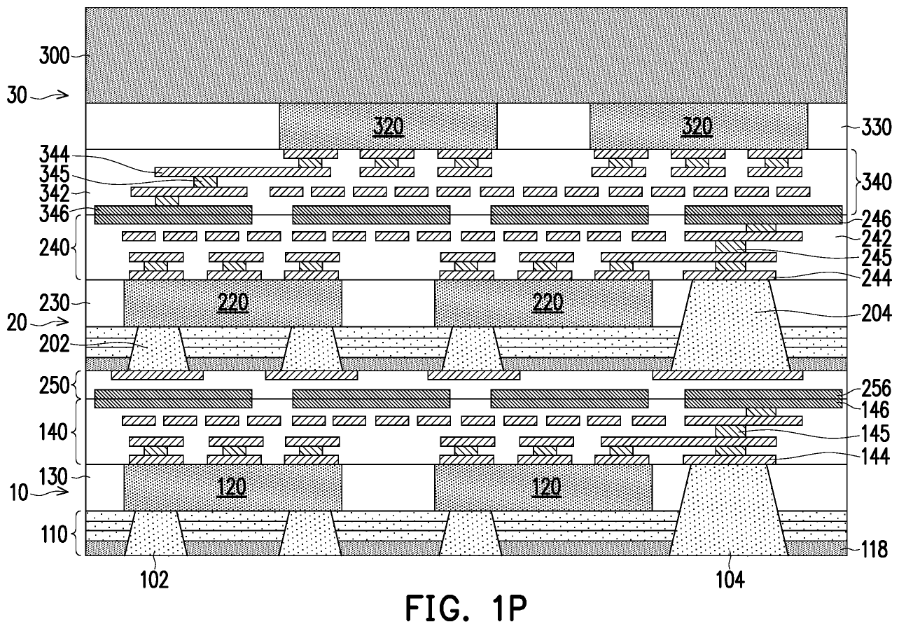

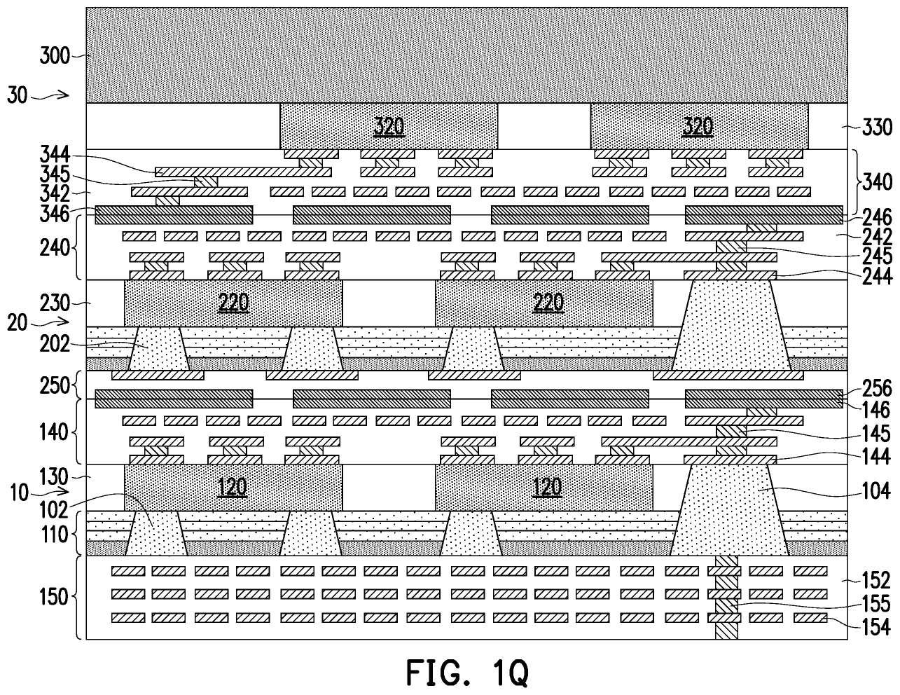

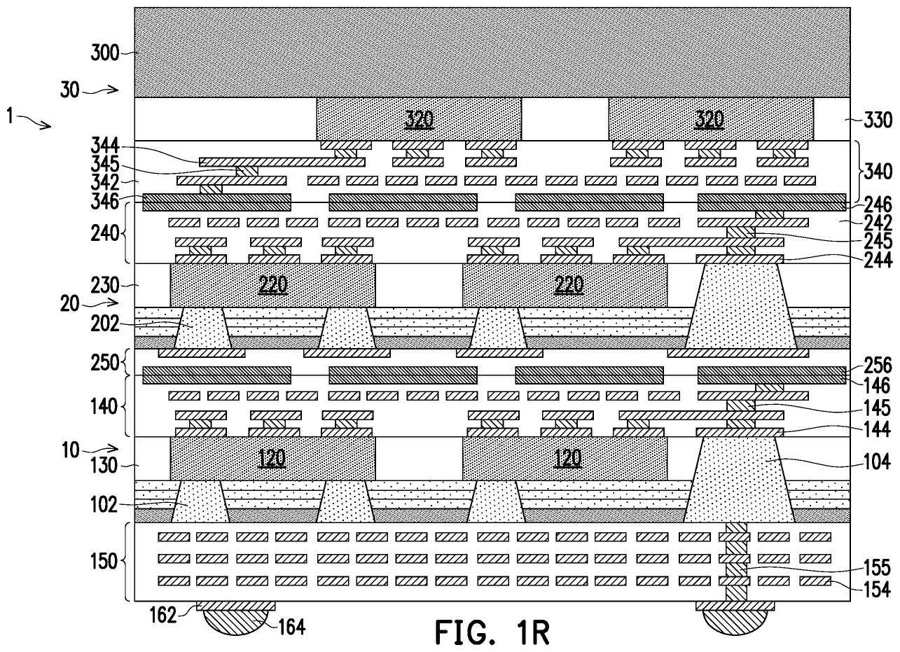

FIGS. 1A to 1R illustrate cross-sectional views of a method for fabricating a three-dimensional integrated circuit stack 1, according to various embodiments of the present disclosure. FIGS. 1A to 1B depict cross-sectional schematic diagrams of some steps involved in forming the first integrated circuit structure 10. FIG. 1C shows an enlarged partial schematic diagram of the first semiconductor device 120 from FIGS. 1A and 1B. FIGS. 1D to 1H illustrate cross-sectional schematic diagrams of some steps in forming the second integrated circuit structure 20. FIG. 1I shows an enlarged partial schematic diagram of the second semiconductor device 220 from FIGS. 1D to 1H. FIGS. 1J to 1K display cross-sectional schematic diagrams of some steps involved in forming the third integrated circuit structure 30. FIG. 1L depicts an enlarged partial schematic diagram of the third semiconductor device 320 from FIGS. 1J to 1K. FIGS. 1M to 1R illustrate cross-sectional schematic diagrams of the steps involved in assembling the first integrated circuit structure 10, second integrated circuit structure 20 and third integrated circuit structure 30.

Referring to FIG. 1A, one or more first semiconductor devices 120 are formed above a first substrate 100, along with a first insulation structure 130 surrounding the first semiconductor devices 120. In some embodiments, the first substrate 100 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or a combination thereof.

The first semiconductor devices 120 can be any type of semiconductor devices. For example, the first semiconductor devices 120 can be, e.g., a microprocessor, an application specific integrated circuit (ASIC), a field programmable gate array (FPGA), a digital signal processor (DSP), or a portion thereof, that includes various passive and active microelectronic devices such as resistors, capacitors, inductors, diodes, p-type field effect transistor (PFET), n-type field effect transistor (NFET), FinFET, Gate-All-Around (GAA) transistor (such as nanosheet FET or nanowire FET), other type of multi-gate FET, metal-oxide semiconductor field effect transistor (MOSFET), complementary metal-oxide semiconductor (CMOS) transistor, bipolar junction transistor (BJT), laterally diffused MOS (LDMOS) transistor, high voltage transistor, high frequency transistor, memory device, other suitable component, or combinations thereof. The exact functionality of the first semiconductor devices 120 is not a limitation to the provided subject matter.

For example, as shown in FIG. 1C, at least one of the first semiconductor devices 120 is a GAA transistor formed on the first substrate 100. The first semiconductor device 120 includes strained layers 120SD, nanosheets 120NS, a gate electrode 120G, spacers 121, inner spacers 122, and a gate dielectric layer 128.

The strained layers 120SD are epitaxially grown from the first substrate 100. In some embodiments, the strained layers 120SD are used to strain or stress the nanosheets (which may be referred to as channel members) 120NS. Herein, the strained layers 120SD may be referred to as “epitaxial layers”, “source/drain region” or “highly doped low resistance materials” in some examples.

The spacers 121 include a dielectric material, such as silicon oxide, silicon nitride, SiON, SiC, SiCN, SiCON, or a combination thereof. Other materials such as a low-k material may be applicable. The low-k material has a dielectric constant less than 3.9, less than 3, less than 2.5, or even less. Although the spacers 121 illustrated in FIG. 1C have a single-layer structure, the embodiments of the present disclosure are not limited thereto. In other embodiments, the spacers 121 may have a multi-layer structure. For example, the spacers 121 may include a silicon oxide layer and a silicon nitride layer on the silicon oxide layer

The inner spacers 122 are formed between the strained layers 120SD. In some embodiments, an inner spacer material is formed on the first substrate 100. In some embodiments, the inner spacer material includes silicon oxide, silicon nitride, silicon carbide, silicon carbide nitride, silicon oxide carbide, silicon carbide oxynitride, and/or other suitable dielectric materials, and may be formed by ALD or a suitable method. In other embodiments, the inner spacer material includes a low-k material having a dielectric constant less than 3.9, less than 3, less than 2.5, or even less.

A contact etching stop layer (CESL) 126 is formed over the strained layers 120SD. In some embodiments, the CESL 126 conformally covers the upper portions of the strained layers 120SD and the sidewalls of the spacers 121. The CESL 126 may include silicon nitride, silicon oxynitride, silicon nitride with oxygen (O) or carbon (C) elements, metal oxide such as Al₂O₃, the like, or a combination thereof, and may be formed by CVD, PVD, ALD, or a suitable process.

An interlayer dielectric (ILD) layer 127 is formed over the CESL 126. In some embodiments, the ILD layer 127 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, the like, or a combination thereof. In some other embodiments, the ILD layer 127 includes a low-k material. The low-k material has a dielectric constant less than 3.9, less than 3, less than 2.5, or even less. Examples of the low-k material include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), the like, or a combination thereof. In other embodiments, the ILD layer 127 may have a single-layer structure or a multi-layer structure. In some embodiments, the ILD layer 127 is formed by FCVD, CVD, HDPCVD, SACVD, spin-on process, sputtering, or a suitable process.

The gate dielectric layer 128 is formed in the gate trench during a metal gate replacement process. For example, between the spacers 121 and the inner spacers 122, there originally exist one or more types of dummy materials (not shown). After removing the aforementioned one or more types of dummy materials, a gate trench is formed between the spacers 121 and the inner spacers 122. Subsequently, a gate dielectric layer 128 is formed within the gate trench. In some embodiments, the gate dielectric layer 128 conformally covers the gate trench to form a U-shape cross-section, and further conformally covers the surface of each gap between the nanosheets 120NS to form a circle-like shape cross-section.

The gate electrode 120G is formed on the gate dielectric layer 128 to surround each of the nanosheets 120NS. In some embodiments, the gate electrode 120G completely fills the gate trench between the spacers 121 and the gaps between the nanosheets 120NS.

In some embodiments, the first insulation structure 130 surrounding the first semiconductor device 120 includes the CESL 126 and the ILD layer 127. In some embodiments, the first insulation structure 130 may also include other structures and/or layers.

In certain embodiments, additional semiconductor device(s) of the same type or different types may be included. The additional semiconductor device(s) may include digital chips, analog chips, or mixed signal chips, such as ASIC chips, sensor chips, wireless and RF chips, memory chips, logic chips, voltage regulator chips, or the like. The disclosure is not limited thereto. It should be appreciated that the illustration of the first semiconductor device 120 and its components throughout all figures is schematic and is not in scale.

Turing to FIG. 1B, a first interconnect structure 140 is formed on the first semiconductor devices 120 and the first insulation structure 130. The first interconnect structure 140 is on the front side of the first integrated circuit structure, and include metallization patterns 144, and metallization vias 145 disposed in a dielectric layer 142. Although the dielectric layer 142 shown in the figures is depicted as a single-layer structure, the present disclosure is not limited thereto. The dielectric layer 142 can be a multilayer structure.

In this embodiment, the metallization patterns 144 include the MD layer, M0 layer, M1 layer, and M2 layer, arranged from bottom to top. The MD layer is the innermost layer closest to the first semiconductor device 120, while the M2 layer is the outermost layer. In this embodiment, the outermost metallization pattern 144 (i.e., M2 layer) serve as the first bonding pads 146.

In some embodiments, the quantity and distribution of metallization patterns 144 and metallization vias 145 can be adjusted according to specific requirements. In some embodiments, a portion of the metallization patterns 144 and/or a portion of the metallization vias 145 are connected to the first semiconductor device 120. For example, as shown in FIG. 1C, a portion of the metallization vias 145 is connected to the gate electrode 120G of the first semiconductor device 120. The metallization via 145 connected to the gate electrode 120G can also be referred to as a gate contact via (not shown in FIG. 1B). In other alternative embodiments, a portion of the metallization vias 145 extend through the CESL 126 and the ILD layer 127 to connect the strained layer 120SD. The metallization via 145 connected to the strained layer 120SD can also be referred to as a source/drain contact via (not shown in FIG. 1B).

Then, referring to FIG. 1D, one or more second semiconductor devices 220 are formed above a second substrate 200, along with a second insulation structure 230 surrounding the second semiconductor devices 220. In some embodiments, the second substrate 200 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP. AlInAs, AlGaAs, GaInAs, GaInP and GaInAsP or a combination thereof.

The second semiconductor devices 220 can be any type of semiconductor devices. For example, the second semiconductor devices 220 can be, e.g., a microprocessor, an application specific integrated circuit (ASIC), a field programmable gate array (FPGA), a digital signal processor (DSP), or a portion thereof, that includes various passive and active microelectronic devices such as resistors, capacitors, inductors, diodes, p-type field effect transistor (PFET), n-type field effect transistor (NFET), FinFET, Gate-All-Around (GAA) transistor (such as nanosheet FET or nanowire FET), other type of multi-gate FET, metal-oxide semiconductor field effect transistor (MOSFET), complementary metal-oxide semiconductor (CMOS) transistor, bipolar junction transistor (BJT), laterally diffused MOS (LDMOS) transistor, high voltage transistor, high frequency transistor, memory device, other suitable component, or combinations thereof. The exact functionality of the second semiconductor devices 220 is not a limitation to the provided subject matter.

For example, as shown in FIG. 1I, at least one of the second semiconductor devices 220 is a GAA transistor formed on the second substrate 200 (not shown in FIG. 1I). The second semiconductor device 220 includes strained layers 220SD, nanosheets 220NS, a gate electrode 220G, spacers 221, inner spacers 222, and a gate dielectric layer 228.

The strained layers 220SD are epitaxially grown from the second substrate 200. In some embodiments, the strained layers 220SD are used to strain or stress the nanosheets (which may be referred to as channel members) 220NS. Herein, the strained layers 220SD may be referred to as “epitaxial layers”, “source/drain region” or “highly doped low resistance materials” in some examples.

The spacers 221 include a dielectric material, such as silicon oxide, silicon nitride, SiON, SiC, SiCN, SiCON, or a combination thereof. Other materials such as a low-k material may be applicable. The low-k material has a dielectric constant less than 3.9, less than 3, less than 2.5, or even less. Although the spacers 221 illustrated in FIG. 1I have a single-layer structure, the embodiments of the present disclosure are not limited thereto. In other embodiments, the spacers 221 may have a multi-layer structure. For example, the spacers 221 may include a silicon oxide layer and a silicon nitride layer on the silicon oxide layer

The inner spacers 222 are formed between the strained layers 220SD. In some embodiments, an inner spacer material is formed on the second substrate 200. In some embodiments, the inner spacer material includes silicon oxide, silicon nitride, silicon carbide, silicon carbide nitride, silicon oxide carbide, silicon carbide oxynitride, and/or other suitable dielectric materials, and may be formed by ALD or a suitable method. In other embodiments, the inner spacer material includes a low-k material having a dielectric constant less than 3.9, less than 3, less than 2.5, or even less.

A CESL 226 is formed over the strained layers 220SD. In some embodiments, the CESL 226 conformally covers the upper portions of the strained layers 220SD and the sidewalls of the spacers 221. The CESL 226 may include silicon nitride, silicon oxynitride, silicon nitride with oxygen (O) or carbon (C) elements, metal oxide such as Al₂O₃, the like, or a combination thereof, and may be formed by CVD, PVD, ALD, or a suitable process.

An ILD layer 227 is formed over the CESL 226. In some embodiments, the ILD layer 227 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, the like, or a combination thereof. In some other embodiments, the ILD layer 227 includes a low-k material. The low-k material has a dielectric constant less than 3.9, less than 3, less than 2.5, or even less. Examples of the low-k material include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), the like, or a combination thereof. In other embodiments, the ILD layer 227 may have a single-layer structure or a multi-layer structure. In some embodiments, the ILD layer 227 is formed by FCVD, CVD. HDPCVD, SACVD, spin-on process, sputtering, or a suitable process.

The gate dielectric layer 228 is formed in the gate trench during a metal gate replacement process. For example, between the spacers 221 and the inner spacers 222, there originally exist one or more types of dummy materials (not shown). After removing the aforementioned one or more types of dummy materials, a gate trench is formed between the spacers 221 and the inner spacers 222. Subsequently, a gate dielectric layer 228 is formed within the gate trench. In some embodiments, the gate dielectric layer 228 conformally covers the gate trench to form a U-shape cross-section, and further conformally covers the surface of each gap between the nanosheets 220NS to form a circle-like shape cross-section.

The gate electrode 220G is formed on the gate dielectric layer 228 to surround each of the nanosheets 220NS. In some embodiments, the gate electrode 220G completely fills the gate trench between the spacers 221 and the gaps between the nanosheets 220NS.

In some embodiments, the second insulation structure 230 surrounding the second semiconductor device 220 includes the CESL 226 and the ILD layer 227. In some embodiments, the second insulation structure 230 may also include other structures and/or layers.

In certain embodiments, additional semiconductor device(s) of the same type or different types may be included. The additional semiconductor device(s) may include digital chips, analog chips, or mixed signal chips, such as ASIC chips, sensor chips, wireless and RF chips, memory chips, logic chips, voltage regulator chips, or the like. The disclosure is not limited thereto. It should be appreciated that the illustration of the second semiconductor device 220 and its components throughout all figures is schematic and is not in scale.

Turing to FIG. 1E, a second interconnect structure 240 is formed on the second semiconductor devices 220 and the second insulation structure 230. The second interconnect structure 240 is on the front side of the second integrated circuit structure, and includes metallization patterns 244 and metallization vias 245 disposed in a dielectric layer 242. Although the dielectric layer 242 shown in the figures is depicted as a single-layer structure, the present disclosure is not limited thereto. The dielectric layer 242 can be a multilayer structure.

In this embodiment, the metallization patterns 244 include the MD layer, M0 layer, M1 layer, and M2 layer, arranged from bottom to top. The MD layer is the innermost layer closest to the second semiconductor device 220, while the M2 layer is the outermost layer. In this embodiment, the outermost metallization pattern 244 (i.e., M2 layer) serve as the second bonding pads 246.

In some embodiments, the quantity and distribution of metallization patterns 244 and metallization vias 245 can be adjusted according to specific requirements. In some embodiments, a portion of the metallization patterns 244 and/or a portion of the metallization vias 245 are connected to the second semiconductor device 220. For example, as shown in FIG. 1I, a portion of the metallization vias 245 is connected to the gate electrode 220G of the second semiconductor device 220. The metallization via 245 connected to the gate electrode 220G can also be referred to as a gate contact via (not shown in FIGS. 1E to 1H). In other alternative embodiments, source/drain contact vias (not shown in FIGS. 1E to 1H) may be formed in the CESL 226 and the ILD layer 227 to connect the strained layer 220SD. A portion of the metallization via 245 may electrically connected to the source/drain contact vias.

Referring to FIG. 1F, the second substrate 200 is removed by gridding process and/or polishing process (e.g. a chemical mechanical polish (CMP) process). Next, the second buffer structure 210 is deposited on one side of the second semiconductor device 220 opposite to the second interconnect structure 240. In the other word, the second buffer structure 210 is on the back side of the second integrated circuit structure. The second buffer structure 210 extends from the second semiconductor device 220 to the second insulation structure 230. The second semiconductor device 220 and the second insulation structure 230 are located between the second buffer structure 210 and the second interconnect structure 240.

In some embodiments, the second buffer structure 210 includes a plurality of insulation layers 212, 214, 216 and a semiconductor layer 218. In some embodiments, the insulation layers 212, 214, 216 may include materials such as silicon oxide, silicon oxycarbide, silicon nitride, silicon oxynitride, silicon nitride with oxygen (O) or carbon (C) elements, metal oxide such as Al₂O₃, or a combination thereof. These layers may be formed using processes such as CVD, PVD, ALD, or other suitable methods. In some embodiments, the semiconductor layer 218 is made of silicon or the like. The insulation layers 212, 214, 216 are disposed between the semiconductor layer 218 and the second semiconductor device 220, as well as between the semiconductor layer 218 and the second insulation structure 230.

Referring to FIG. 1G, one or more of second conductive vias 202 and at least one of second through via 204 are formed in the second buffer structure 210. For example, a patterned photoresist layer is first formed on the second buffer structure 210 through photolithography. Then, using the aforementioned patterned photoresist layer as a mask, one or more etching processes are performed to create openings that pass through the second buffer structure 210. Openings for forming the second conductive vias 202 pass through the second buffer structure 210 and expose at least a portion of the second semiconductor devices 220. Opening for forming the second through via 204 passes through the second buffer structure 210 and the second insulation structure 230 and expose at least a portion of the second interconnect structure 240. In some embodiments, the openings for forming the second conductive vias 202 and the opening for forming the second through via 204 are formed in the same etching process. For example, by adjusting the hole density and/or size in the aforementioned patterned photoresist layer, openings of different sizes are formed in the second buffer structure 210. The opening for forming the second through via 204 has a larger size, while the openings for forming the second conductive vias 202 have a smaller size. Subsequently, a conductive material is deposited into the openings, and then a planarization process (such as CMP process) is employed to remove the excess conductive material beyond the second buffer structure 210, thereby obtaining the second conductive vias 202 and the second through via 204. In some embodiments, top surfaces of the second conductive vias 202 are coplanar with a top surface of the second through via 204 and a top surface of the semiconductor layer 218 of the second buffer structure 210. The thickness of the second through via 204 is larger than a thickness of the second conductive vias 202.

In some embodiments, the second conductive vias 202 are directly in contact with the strained layers 220SD (the source/drain region) of the second semiconductor device 220, as shown in FIG. 1I. In this embodiment, the density of the second semiconductor device 220 can be improved because the second conductive vias 202 pass through the second buffer structure 210 without extending into the second insulation structure 230. For example, in some cases, the second conductive vias 202 pass through the second insulation structure 230 and then electrically connects to the second semiconductor devices 220 via the second interconnect structure 240. However, this type of second conductive via 202 occupies the space between the second semiconductor devices 220, limiting the number of transistors that can be accommodated per unit area. Therefore, the density of the second semiconductor devices 220 can be enhanced by utilizing the second conductive via 202 that does not pass through the second insulation structure 230.

Additionally, in some embodiments, the larger width of the second through via 204 allows them to be utilized as super power rail (SPR). In this embodiment, the second through via 204 passes through the second insulation structure 230 (which may include inorganic insulating materials) instead of being formed in subsequent organic encapsulation materials on the outer side of the die, if such organic encapsulation materials are present. As a result, the overall device size can be reduced.

Turing to FIG. 1H, the third interconnect structure 250 is formed on the second buffer structure 210. The second buffer structure 210 is disposed between the third interconnect structure 250 and the second semiconductor devices 220.

The third interconnect structure 250 includes metallization patterns 254 and metallization vias (not shown) disposed in a dielectric layer 252. Although the dielectric layer 252 shown in the figures is depicted as a single-layer structure, the present disclosure is not limited thereto. The dielectric layer 252 can be a multilayer structure.

In this embodiment, the metallization patterns 254 include the BM0 layer and BM1 layer, arranged from bottom to top. The BM0 layer is the innermost layer closest to the second buffer structure 210, while the BM1 layer is the outermost layer. In this embodiment, the outermost metallization pattern 254 (i.e., BM1 layer) serve as the third bonding pads 256.

In some embodiments, the quantity and distribution of metallization patterns 254 and metallization vias in the third interconnect structure 250 can be adjusted according to specific requirements. In some embodiments, the third interconnect structure 250 is electrically connected to the second semiconductor devices 220 through the second conductive vias 202, and the third interconnect structure 250 is electrically connected to the second interconnect structure 240 through the second through via 204. The second conductive vias 202 are extending from the third interconnect structure 250 to the second semiconductor devices 220, and the second through via 204 is extending from the third interconnect structure 250 to the second interconnect structure 240.

Then, referring to FIG. 1J, one or more third semiconductor devices 320 are formed above a third substrate 300, along with a third insulation structure 330 surrounding the third semiconductor devices 320. In some embodiments, the third substrate 300 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or a combination thereof.

The third semiconductor devices 320 can be any type of semiconductor device. For example, the third semiconductor devices 320 can be, e.g., a microprocessor, an application specific integrated circuit (ASIC), a field programmable gate array (FPGA), a digital signal processor (DSP), or a portion thereof, that includes various passive and active microelectronic devices such as resistors, capacitors, inductors, diodes, p-type field effect transistor (PFET), n-type field effect transistor (NFET), FinFET, Gate-All-Around (GAA) transistor (such as nanosheet FET or nanowire FET), other type of multi-gate FET, metal-oxide semiconductor field effect transistor (MOSFET), complementary metal-oxide semiconductor (CMOS) transistor, bipolar junction transistor (BJT), laterally diffused MOS (LDMOS) transistor, high voltage transistor, high frequency transistor, memory device, other suitable component, or combinations thereof. The exact functionality of the third semiconductor devices 320 is not a limitation to the provided subject matter.

For example, as shown in FIG. 1L, at least one of the third semiconductor devices 320 is a GAA transistor formed on the third substrate 300 (not shown in FIG. 1L). The third semiconductor device 320 includes strained layers 320SD, nanosheets 320NS, a gate electrode 320G, spacers 321, inner spacers 322, and a gate dielectric layer 328.

The strained layers 320SD are epitaxially grown from the third substrate 300. In some embodiments, the strained layers 320SD are used to strain or stress the nanosheets (which may be referred to as channel members) 320NS. Herein, the strained layers 320SD may be referred to as “epitaxial layers”, “source/drain region” or “highly doped low resistance materials” in some examples.

The spacers 321 include a dielectric material, such as silicon oxide, silicon nitride, SiON, SiC, SiCN, SiCON, or a combination thereof. Other materials such as a low-k material may be applicable. The low-k material has a dielectric constant less than 3.9, less than 3, less than 2.5, or even less. Although the spacers 321 illustrated in FIG. 1L have a single-layer structure, the embodiments of the present disclosure are not limited thereto. In other embodiments, the spacers 321 may have a multi-layer structure. For example, the spacers 321 may include a silicon oxide layer and a silicon nitride layer on the silicon oxide layer

The inner spacers 322 are formed between the strained layers 320SD. In some embodiments, an inner spacer material is formed on the third substrate 300. In some embodiments, the inner spacer material includes silicon oxide, silicon nitride, silicon carbide, silicon carbide nitride, silicon oxide carbide, silicon carbide oxynitride, and/or other suitable dielectric materials, and may be formed by ALD or a suitable method. In other embodiments, the inner spacer material includes a low-k material having a dielectric constant less than 3.9, less than 3, less than 2.5, or even less.

A CESL 326 is formed over the strained layers 320SD. In some embodiments, the CESL 326 conformally covers the upper portions of the strained layers 320SD and the sidewalls of the spacers 321. The CESL 326 may include silicon nitride, silicon oxynitride, silicon nitride with oxygen (O) or carbon (C) elements, metal oxide such as Al₂O₃, the like, or a combination thereof, and may be formed by CVD, PVD, ALD, or a suitable process.

An ILD layer 327 is formed over the CESL 326. In some embodiments, the ILD layer 327 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, the like, or a combination thereof. In some other embodiments, the ILD layer 327 includes a low-k material. The low-k material has a dielectric constant less than 3.9, less than 3, less than 2.5, or even less. Examples of the low-k material include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), the like, or a combination thereof. In other embodiments, the ILD layer 327 may have a single-layer structure or a multi-layer structure. In some embodiments, the ILD layer 327 is formed by FCVD. CVD. HDPCVD, SACVD, spin-on process, sputtering, or a suitable process.

The gate dielectric layer 328 is formed in the gate trench during a metal gate replacement process. For example, between the spacers 321 and the inner spacers 322, there originally exist one or more types of dummy materials (not shown). After removing the aforementioned one or more types of dummy materials, a gate trench is formed between the spacers 321 and the inner spacers 322. Subsequently, a gate dielectric layer 328 is formed within the gate trench. In some embodiments, the gate dielectric layer 328 conformally covers the gate trench to form a U-shape cross-section, and further conformally covers the surface of each gap between the nanosheets 320NS to form a circle-like shape cross-section.

The gate electrode 320G is formed on the gate dielectric layer 328 to surround each of the nanosheets 320NS. In some embodiments, the gate electrode 320G completely fills the gate trench between the spacers 321 and the gaps between the nanosheets 320NS.

In some embodiments, the third insulation structure 330 surrounding the third semiconductor device 320 includes the CESL 326 and the ILD layer 327. In some embodiments, the third insulation structure 330 may also include other structures and/or layers.

In some embodiments, source/drain contact vias 329 are formed in the CESL 326 and the ILD layer 327 to connect the strained layer 320SD. For example, by using an etching process, openings passing through the CESL 326 and the ILD layer 327 are formed, thereby exposing the strained layer 320SD. Then, the openings are filled with a conductive material to form source/drain contact vias 329. In some embodiments, the top surface of the source/drain contact vias 329 aligns with the top surface of the gate electrode 320G.

In certain embodiments, additional semiconductor device(s) of the same type or different types may be included. The additional semiconductor device(s) may include digital chips, analog chips, or mixed signal chips, such as ASIC chips, sensor chips, wireless and RF chips, memory chips, logic chips, voltage regulator chips, or the like. The disclosure is not limited thereto. It should be appreciated that the illustration of the third semiconductor device 320 and its components throughout all figures is schematic and is not in scale.

Turing to FIG. 1K, a fourth interconnect structure 340 is formed on the third semiconductor devices 320 and the third insulation structure 330. The fourth interconnect structure 340 is on the front side of the third integrated circuit structure, and includes metallization patterns 344 and metallization vias 345 disposed in a dielectric layer 342. Although the dielectric layer 342 shown in the figures is depicted as a single-layer structure, the present disclosure is not limited thereto. The dielectric layer 342 can be a multilayer structure.

In this embodiment, the metallization patterns 344 include the MD layer, M0 layer, M1 layer, and M2 layer, arranged from bottom to top. The MD layer is the innermost layer closest to the third semiconductor device 320, while the M2 layer is the outermost layer. In this embodiment, the outermost metallization pattern 344 (i.e., M2 layer) serve as the fourth bonding pads 346.

In some embodiments, the quantity and distribution of metallization patterns 344 and vias 345 can be adjusted according to specific requirements. In some embodiments, a portion of the metallization patterns 344 and/or a portion of the metallization vias 345 are connected to the third semiconductor devices 320. For example, as shown in FIG. 1L, a portion of the vias 345 is connected to the gate electrode 320G and the source/drain contact vias 329 of the third semiconductor device 320. The via 345 connected to the gate electrode 320G can also be referred to as a gate contact via (not shown in FIG. 1K).

In some embodiments, the third substrate 300 may be optionally ground to adjust the thickness of the device. In some embodiments, the third substrate 300 can be used as a heat dissipation layer, thus retaining at least a portion of the third substrate 300 can improve the thermal budget issue of the subsequently formed three-dimensional integrated circuit stack.

Next, referring to FIG. 1M, where the second integrated circuit structure 20 shown in FIG. 1H is bonded to the first integrated circuit structure 10 shown in FIG. 1B. For example, the third interconnect structure 250 of the second integrated circuit structure 20 is bonded to the first interconnect structure 140 of the first integrated circuit structure 10 using hybrid bonding technology. As a result, there is a metal-to-metal bonding between the first bonding pads 146 and the third bonding pads 256, and a dielectric-to-dielectric bonding between the dielectric layer 142 and the dielectric layer 252.

In some embodiments, the second integrated circuit structure 20 is bonding to the first integrated circuit structure 10 in a front-to-back manner by wafer-on-wafer (WoW) or chip-on wafer (CoW) stacking. When the second integrated circuit structure 20 is bonded to the first integrated circuit structure 10 by CoW stacking, the second integrated circuit structure 20 is first subjected to a dicing process before the bonding process.

Then, as shown in FIG. 1N, the third integrated circuit structure 30 shown in FIG. 1K is bonded to the second integrated circuit structure 20. For example, the fourth interconnect structure 340 of the third integrated circuit structure 30 is bonded to the second interconnect structure 240 of the second integrated circuit structure 20 using hybrid bonding technology. As a result, there is a metal-to-metal bonding between the fourth bonding pads 346 and the second bonding pads 246, and a dielectric-to-dielectric bonding between the dielectric layer 342 and the dielectric layer 242.

In some embodiments, the third integrated circuit structure 30 is bonding to the second integrated circuit structure 20 in a front-to-front manner by chip-on-chip (COC), WoW or CoW stacking. When the third integrated circuit structure 20 is bonded to the second integrated circuit structure 10 by CoC or CoW stacking, the third integrated circuit structure 30 is first subjected to a dicing process before the bonding process.

Referring to FIG. 1O, the first substrate 100 is removed by gridding process and/or polishing process (e.g. a chemical mechanical polish (CMP) process). Next, the first buffer structure 110 is deposited on one side of the first semiconductor device 120 opposite to the first interconnect structure 140. In the other word, the first buffer structure 110 is on the back side of the first integrated circuit structure 10. The first buffer structure 110 extends from the first semiconductor device 120 to the first insulation structure 130. The first semiconductor device 120 and the first insulation structure 130 are located between the first buffer structure 110 and the first interconnect structure 140.

In some embodiments, the first buffer structure 110 includes a plurality of insulation layers 112, 114, 116 and a semiconductor layer 118. In some embodiments, the insulation layers 112, 114, 116 may include materials such as silicon oxide, silicon oxycarbide, silicon nitride, silicon oxynitride, silicon nitride with oxygen (O) or carbon (C) elements, metal oxide such as Al₂O₃, or a combination thereof. These layers may be formed using processes such as CVD, PVD, ALD, or other suitable methods. In some embodiments, the semiconductor layer 118 is made of silicon or the like. The insulation layers 112, 114, 116 are disposed between the semiconductor layer 118 and the first semiconductor device 120, as well as between the semiconductor layer 118 and the first insulation structure 130.

Referring to FIG. 1P, one or more of first conductive vias 102 and at least one of second through via 104 are formed in the first buffer structure 110. For example, a patterned photoresist layer is first formed on the first buffer structure 110 through photolithography. Then, using the aforementioned patterned photoresist layer as a mask, one or more etching processes are performed to create openings that pass through the first buffer structure 110. Openings for forming the first conductive vias 102 pass through the first buffer structure 110 and expose at least a portion of the first semiconductor devices 120. Opening for forming the first through via 104 passes through the first buffer structure 110 and the first insulation structure 130 and expose at least a portion of the first interconnect structure 140. In some embodiments, the openings for forming the first conductive vias 102 and the opening for forming the first through via 104 are formed in the same etching process. For example, by adjusting the hole density and/or size in the aforementioned patterned photoresist layer, openings of different sizes are formed in the first buffer structure 110. The opening for forming the first through via 104 has a larger size, while the openings for forming the first conductive vias 102 have a smaller size. Subsequently, a conductive material is deposited into the openings, and then a planarization process (such as CMP process) is employed to remove the excess conductive material beyond the first buffer structure 110, thereby obtaining the first conductive vias 102 and the first through via 104. In some embodiments, bottom surfaces of the first conductive vias 102 are coplanar with a bottom surface of the first through via 104 and a bottom surface of the semiconductor layer 118 of the first buffer structure 110. The thickness of the first through via 104 is larger than a thickness of the first conductive vias 102.

In some embodiments, the first conductive vias 102 are directly in contact with the strained layers 120SD (the source/drain region) of the first semiconductor device 120 (referring to FIG. 1I). In this embodiment, the density of the first semiconductor device 120 can be improved because the first conductive vias 102 pass through the first buffer structure 110 without extending into the first insulation structure 130. For example, in some cases, the first conductive vias 102 pass through the first insulation structure 130 and then electrically connects to the first semiconductor devices 120 via the first interconnect structure 140. However, this type of first conductive via 102 occupies the space between the first semiconductor devices 120, limiting the number of transistors that can be accommodated per unit area. Therefore, the density of the first semiconductor devices 120 can be enhanced by utilizing the first conductive via 102 that does not pass through the first insulation structure 130.

Additionally, in some embodiments, the larger width of the first through via 104 allows them to be utilized as super power rail (SPR). In this embodiment, the first through via 104 is electrically connected to the second through via 204 through the first interconnect structure 140 and the third interconnect structure 250. The first through via 104 and the second through via 204 can be used together as a super power rail (SPR). Since the first through via 104 passes through the first buffer structure 110 and the first insulation structure 130, while the second through via 204 passes through the second buffer structure 210 and the second insulation structure 230, the SPR that includes the first through via 104 and the second through via 204 has lower resistance, improving thermal constraint issues and IR drop issues.

Referring to FIGS. 1Q and 1R, a redistribution structure 150 is formed on the first buffer structure 110 of the first integrated circuit structure 10. The redistribution structure 150 includes dielectric structure 152 and metallization patterns 154 (sometimes referred to as redistribution layers or redistribution lines) among the dielectric structure 152. For example, the redistribution structure 150 may include a plurality of metallization patterns 154 separated from each other by the dielectric structure 152. The dielectric structure 152 may comprise multiple layers. In some embodiments, the redistribution structure 150 includes multiple metallization vias 155, which are used to connect metallization patterns 154 located in different layers. In some embodiments, the redistribution structure 150 includes a backside signal routing, power/ground routing, or the combination thereof, or the like.

In some embodiments, the redistribution structure 150 is electrically connected to the first semiconductor devices 120 through the first conductive vias 102, and electrically connected to the first interconnect structure 140 through the first through via 104.

The bonding pads 162 and the conductive connectors 164 may be disposed on the redistribution structure 150. In some embodiments, the bonding pads 162 may be under bump metallization (UBM) pads for mounting conductive connectors 164, such as metal pillars, microbumps or the like. The bonding pads 162 may include a metal or a metal alloy. The bonding pads 162 may include aluminum, copper, nickel, an alloy thereof, or the like, for example. Other suitable pad materials may be within the contemplated scope of disclosure.

In the embodiment, the three-dimensional integrated circuit stack 1 includes a stack of the first integrated circuit structure 10, the second integrated circuit structure 20, and the third integrated circuit structure 30. The first integrated circuit structure 10, the second integrated circuit structure 20, and the third integrated circuit structure 30 in the three-dimensional integrated circuit stack 1 can also be referred to as Tier 1 die, Tier 2 die, and Tier 3 die, respectively. In this embodiment, the thermal constraint issues and IR drop issues in the Tier 2 die and the Tier 3 die can be improved by utilizing the first through via 104 and the second through via 204.

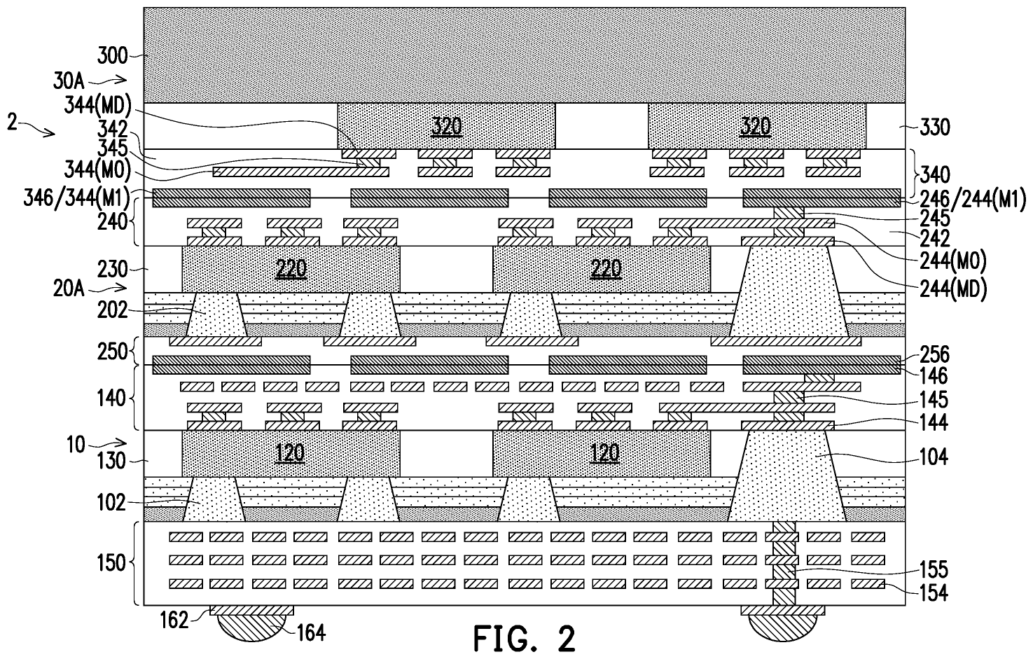

FIG. 2 illustrates a cross-sectional view of a three-dimensional integrated circuit stack 2, in accordance with some alternative embodiments. The difference between the three-dimensional integrated circuit stack 2 in FIG. 2 and the three-dimensional integrated circuit stack 1 in FIG. 1R is that: in the three-dimensional integrated circuit stack 2, the second interconnect structure 240 of the second integrated circuit structure 20A has fewer metallization patterns 244, and the fourth interconnect structure 340 of the third integrated circuit structure 30A has fewer metallization patterns 344.

In this embodiment, the metallization patterns 244 include the MD layer, M0 layer, and M1 layer. The MD layer is the innermost layer of the second interconnect structure 240 closest to the second semiconductor device 220, while the M1 layer is the outermost layer of the second interconnect structure 240. In this embodiment, the outermost metallization pattern 244 (i.e., M1 layer) serve as the second bonding pads 246.

In this embodiment, the metallization patterns 344 include the MD layer, M0 layer, and M1 layer. The MD layer is the innermost layer of the fourth interconnect structure 340 closest to the third semiconductor device 320, while the M1 layer is the outermost layer of the fourth interconnect structure 340. In this embodiment, the outermost metallization pattern 344 (i.e., M1 layer) serve as the fourth bonding pads 346.

In the three-dimensional integrated circuit stack 2 shown in FIG. 2, the second integrated circuit structure 20A and the third integrated circuit structure 30A are bonded together through hybrid bonding between the M1 layer of the second interconnect structure 240 and the M1 layer of the fourth interconnect structure 340. On the other hand, in the three-dimensional integrated circuit stack 1 shown in FIG. 1, the second integrated circuit structure 20 and the third integrated circuit structure 30 are bonded together through hybrid bonding between the M2 layer of the second interconnect structure 240 and the M2 layer of the fourth interconnect structure 340.

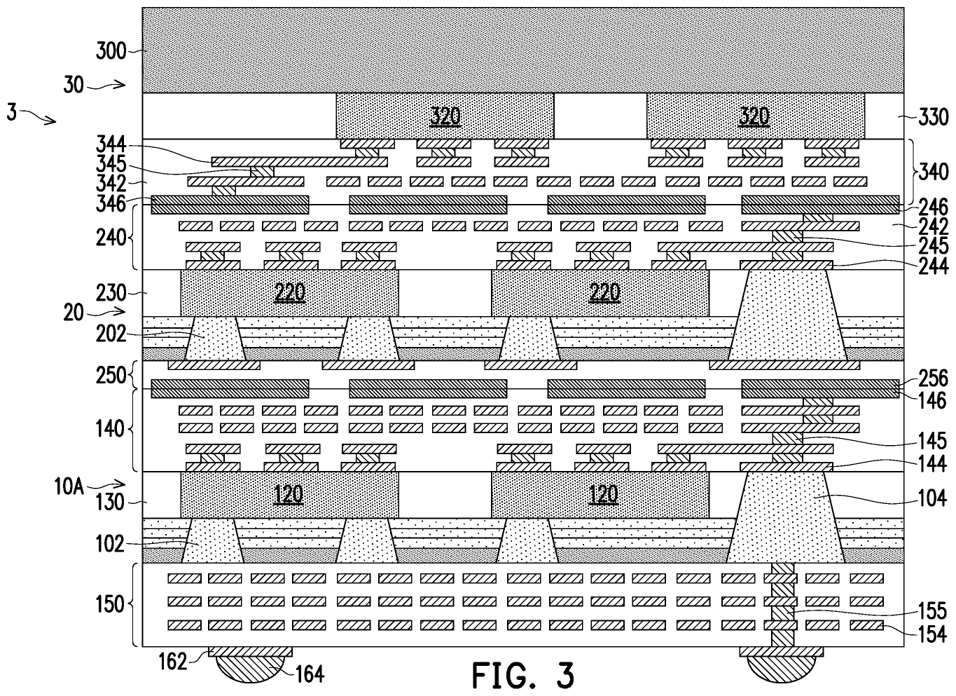

FIG. 3 illustrates a cross-sectional view of a three-dimensional integrated circuit stack 3, in accordance with some alternative embodiments. The difference between the three-dimensional integrated circuit stack 3 in FIG. 3 and the three-dimensional integrated circuit stack 1 in FIG. 1R is that: in the three-dimensional integrated circuit stack 3, the first interconnect structure 140 of the first integrated circuit structure 10A has more metallization patterns 144. In the three-dimensional integrated circuit stack 3, the first interconnect structure 140 may include a frontside signal routing, thereby reducing the number of metallization patterns 154 in the redistribution structure 150. In other words, the backside signal routing disposed in the redistribution structure 150 can be partially or entirely moved into the first interconnect structure 140.

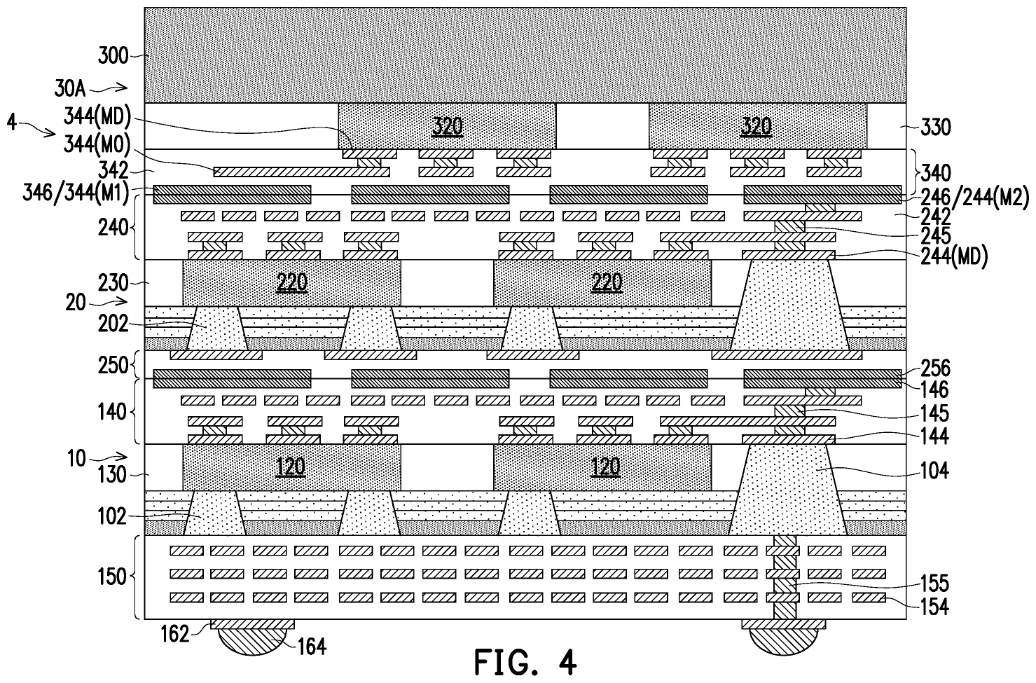

FIG. 4 illustrates a cross-sectional view of a three-dimensional integrated circuit stack 4, in accordance with some alternative embodiments. The difference between the three-dimensional integrated circuit stack 4 in FIG. 4 and the three-dimensional integrated circuit stack 1 in FIG. 1R is that: in the three-dimensional integrated circuit stack 4, the fourth interconnect structure 340 of the third integrated circuit structure 30A has fewer metallization patterns 344.

In this embodiment, the metallization patterns 344 include the MD layer, M0 layer, and M1 layer. The MD layer is the innermost layer of the fourth interconnect structure 340 closest to the third semiconductor device 320, while the M1 layer is the outermost layer of the fourth interconnect structure 340. In this embodiment, the outermost metallization pattern 344 (i.e., M1 layer) serve as the fourth bonding pads 346.

In the three-dimensional integrated circuit stack 4 shown in FIG. 4, the second integrated circuit structure 20 and the third integrated circuit structure 30A are bonded together through hybrid bonding between the M2 layer of the second interconnect structure 240 and the M1 layer of the fourth interconnect structure 340.

In addition, in some embodiments, the third semiconductor devices 320 and/or the second semiconductor devices 220 include a complementary FET (CFET) consisting of an nMOS device and a pMOS device.

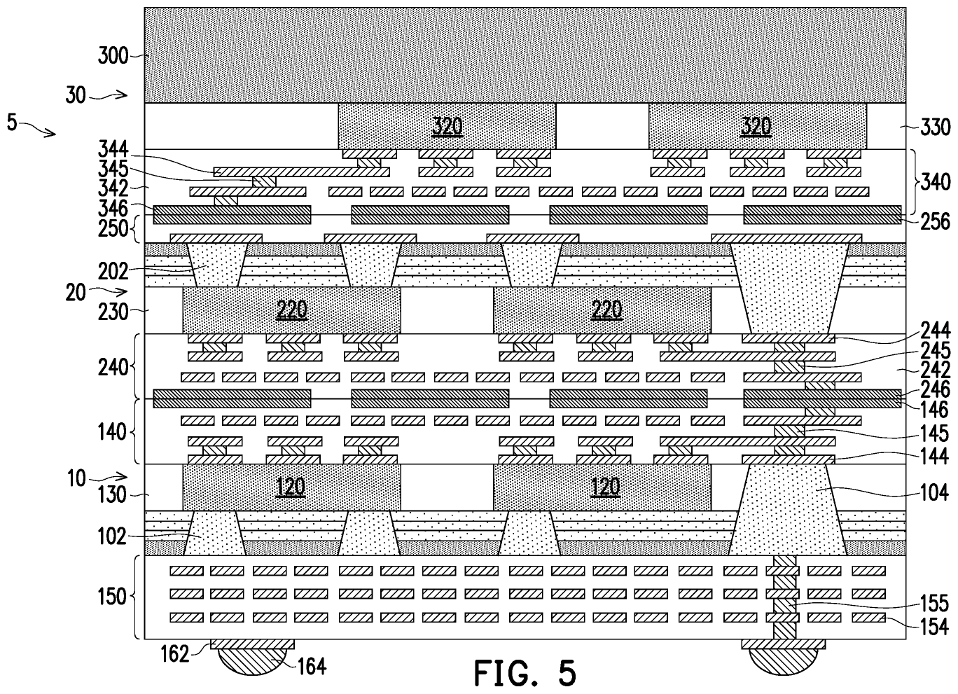

FIG. 5 illustrates a cross-sectional view of a three-dimensional integrated circuit stack 5, in accordance with some alternative embodiments. The difference between the three-dimensional integrated circuit stack 5 in FIG. 5 and the three-dimensional integrated circuit stack 1 in FIG. 1R is that: in the three-dimensional integrated circuit stack 5, the second interconnect structure 240 of the second integrated circuit structure 20 is bonded to the first interconnect structure 140 of the first integrated circuit structure 10, while the third interconnect structure 250 of the second integrated circuit structure 20 is bonded to the fourth interconnect structure 340 of the third integrated circuit structure 30. The second bonding pads 246 are bonded with the first bonding pads 146, and the third bonding pads 256 are bonded with the fourth bonding pads 346.

In the three-dimensional integrated circuit stack 5, the second integrated circuit structure 20 is bonding to the first integrated circuit structure 10 in a front-to-front manner, and the second integrated circuit structure 20 is bonding to the third integrated circuit structure 30 in a front-to-back manner.

A width of a top surface of the first conductive via 102 facing towards the second integrated circuit structure 20 is smaller than a width of a bottom surface of the first conductive via 102 facing away from the second integrated circuit structure 20. A width of a top surface of the first through via 104 facing towards the second integrated circuit structure 20 is smaller than a width of a bottom surface of the first through via 104 facing away from the second integrated circuit structure 20.

A width of a bottom surface of the second conductive via 202 facing towards the first integrated circuit structure 10 is smaller than a width of a top surface of the second conductive via 202 facing away from the first integrated circuit structure 10. A width of a bottom surface of the second through via 204 facing towards the first integrated circuit structure 10 is smaller than a width of a top surface of the second through via 204 facing away from the first integrated circuit structure 10.

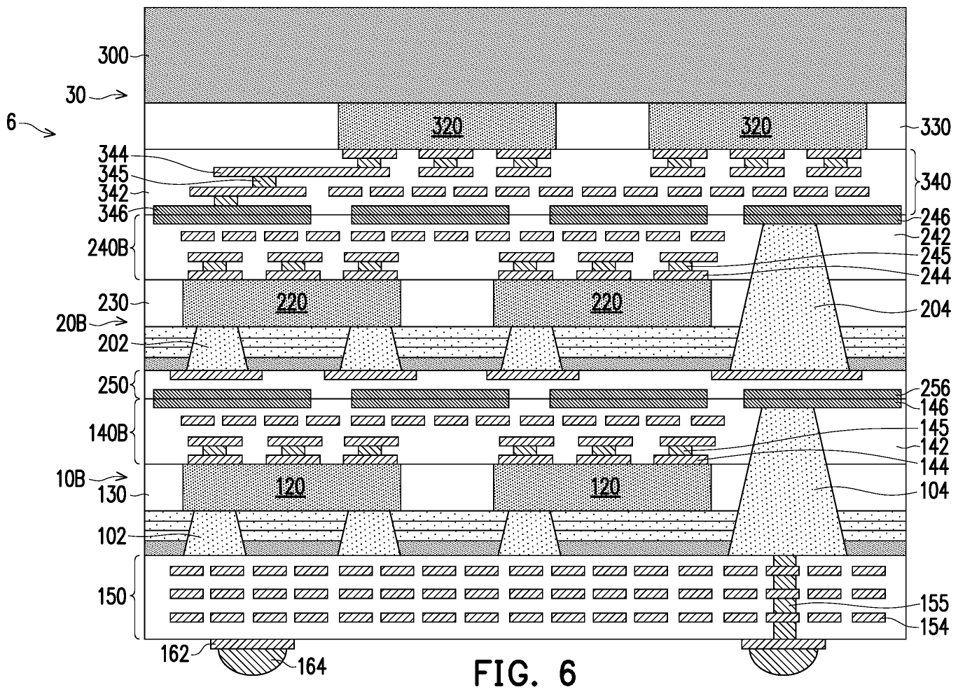

FIG. 6 illustrates a cross-sectional view of a three-dimensional integrated circuit stack 6, in accordance with some alternative embodiments. The difference between the three-dimensional integrated circuit stack 6 in FIG. 6 and the three-dimensional integrated circuit stack 1 in FIG. 1R is that: in the three-dimensional integrated circuit stack 6, the first through via 104 extends from one side of the first buffer structure 110 into the first interconnect structure 140B, while the second through via 204 extends from one side of the second buffer structure 210 into the second interconnect structure 240B.

Referring to FIG. 6, the first through via 104 extends into the dielectric layer 142 of the first interconnect structure 140B and makes contact with the first bonding pad 146 after passing through multiple layers of metallization patterns 144. Similarly, the second through via 204 extends into the dielectric layer 242 of the second interconnect structure 240B and makes contact with the second bonding pad 246 after passing through multiple layers of metallization patterns 244.

Since the first through via 104 does not require any additional connections through other metallization patterns 144 or metallization vias 145 to reach the first bonding pad 146, and the second through via 204 does not require any additional connections through other metallization patterns 244 or metallization vias 245 to reach the second bonding pad 246, the SPR including the first through via 104 and the second through via 204 may have lower resistance.

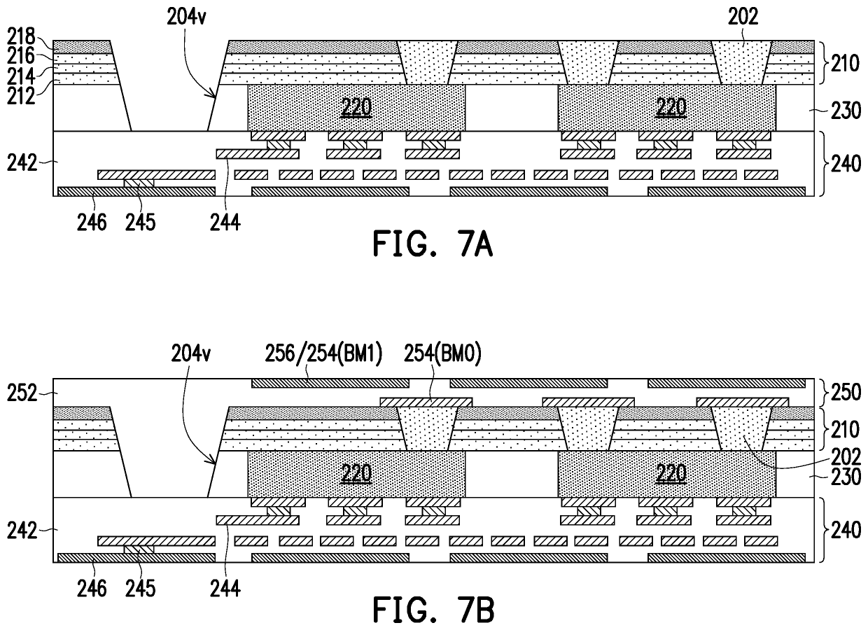

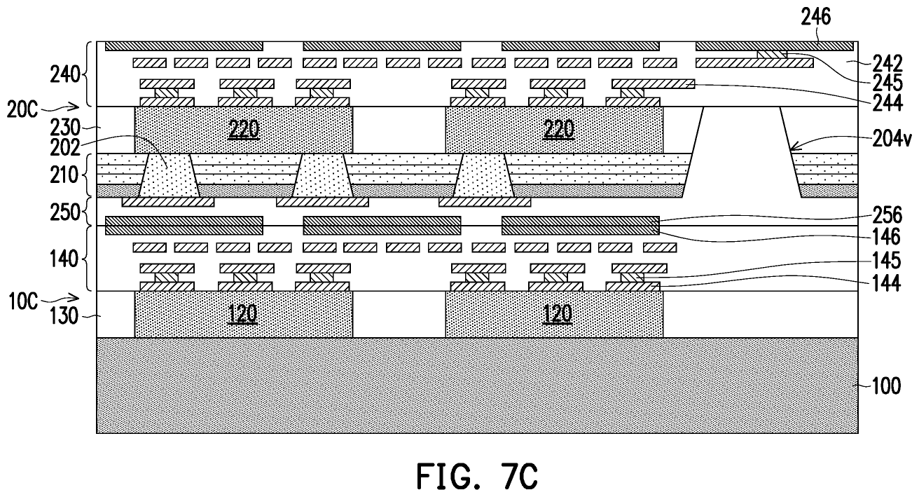

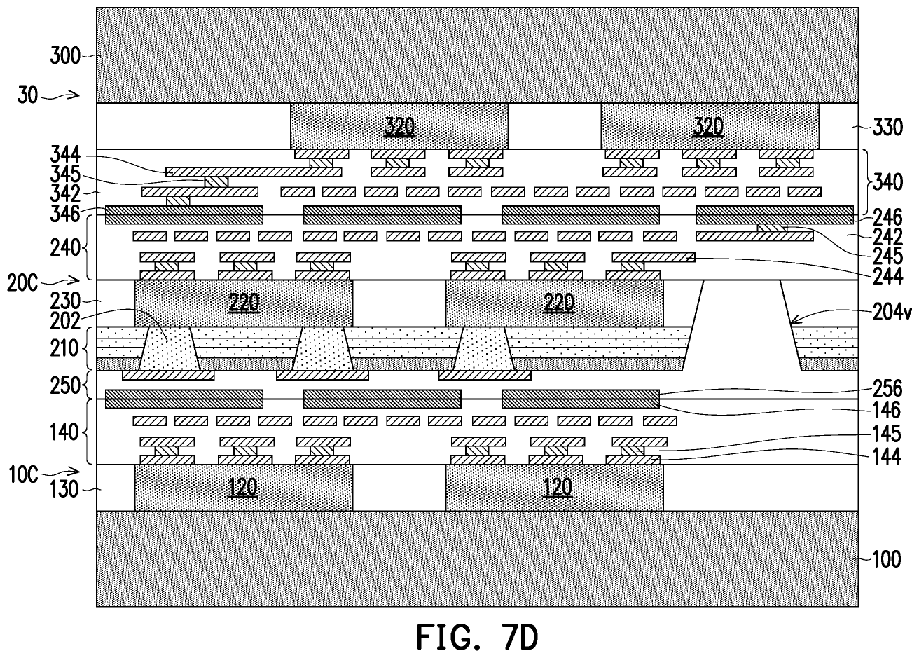

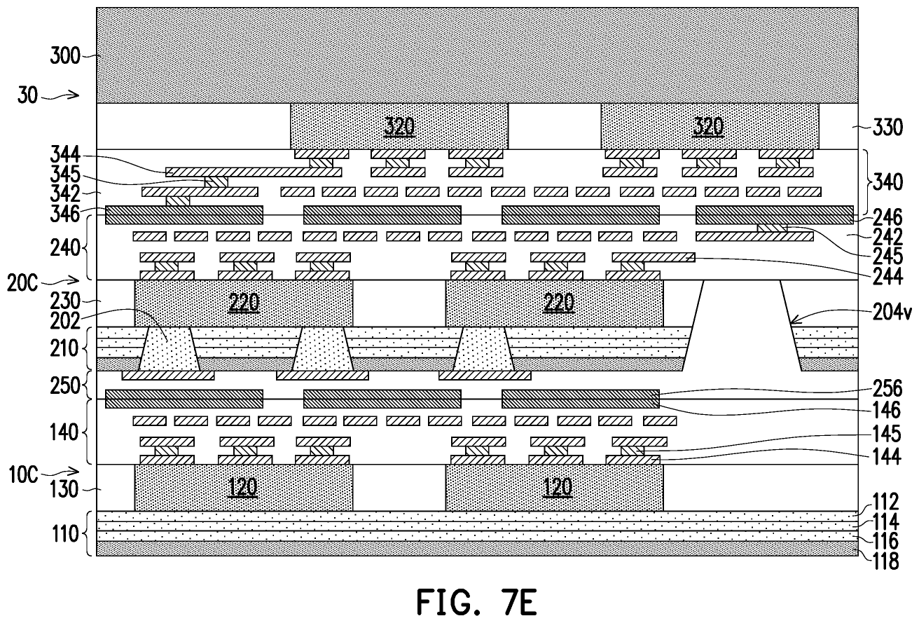

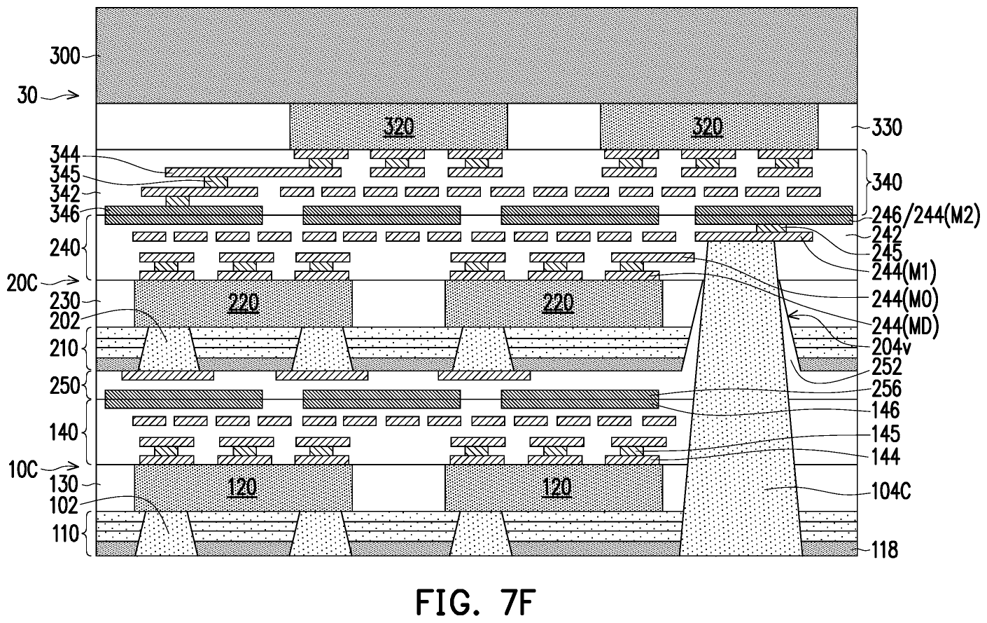

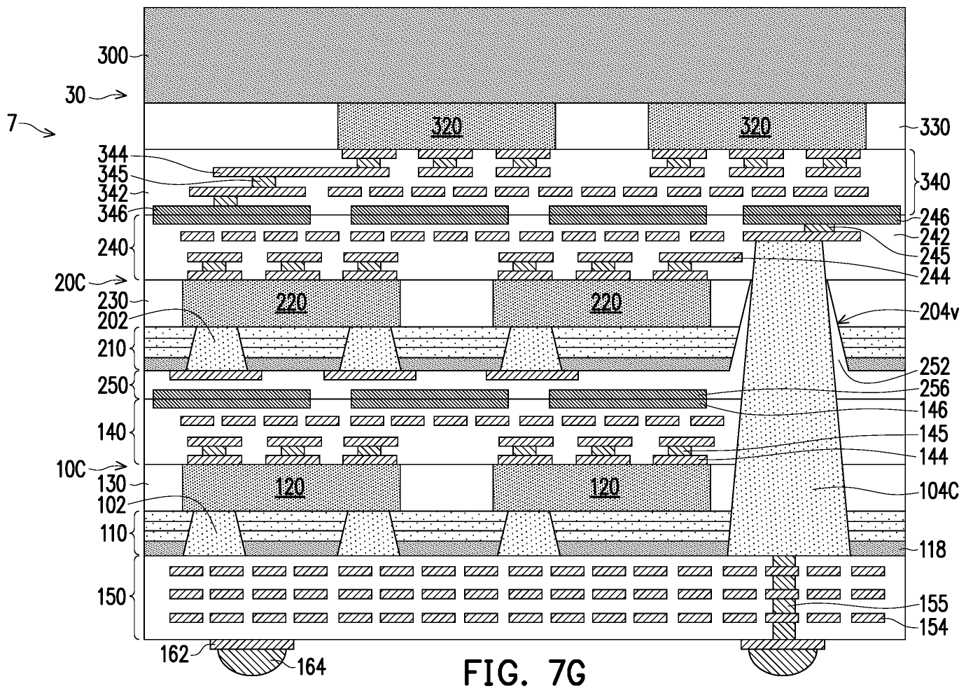

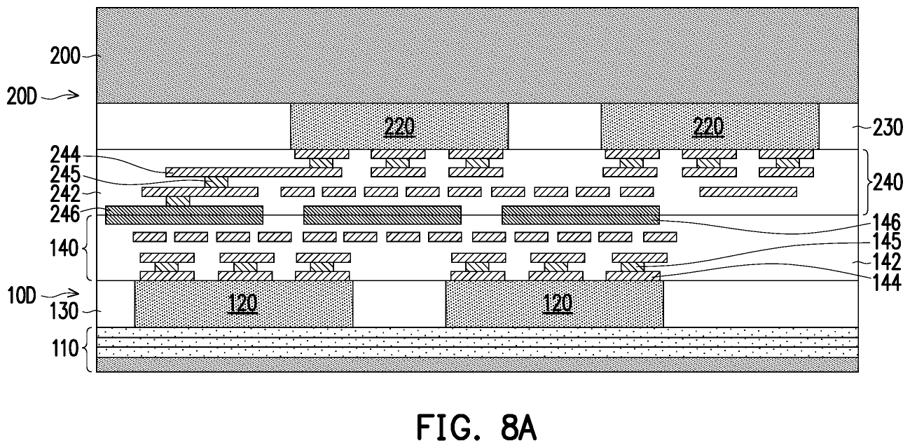

FIGS. 7A to 7G illustrate cross-sectional views of a method for fabricating a three-dimensional integrated circuit stack 7, according to various embodiments of the present disclosure. FIGS. 7A to 7B depict cross-sectional schematic diagrams of some steps involved in forming the second integrated circuit structure 20C. FIGS. 7C to 7G demonstrate cross-sectional schematic diagrams of the steps involved in assembling the first integrated circuit structure 10C, second integrated circuit structure 20C, and third integrated circuit structure 30.

Referring to FIG. 7A, an opening 204v is formed to expose the second interconnect structure 240. In some embodiments, the opening 204v can be formed together with the opening for accommodating the second conductive vias 202. That is, the opening 204v and the opening for accommodating the second conductive vias 202 may be formed in the same etching process. Alternatively, the opening 204v can be formed after the formation of the conductive material of the second conductive vias 202. The opening 204v is passing through the second buffer structure 210 and the second insulation structure 230.

Turning to FIG. 7B, the third interconnect structure 250 is formed on the second buffer structure 210. The third interconnect structure 250 includes metallization patterns 254 and metallization vias (not shown) embedded in a dielectric layer 252. In this embodiment, the dielectric layer 252 is filled into the opening 204v. The metallization patterns 254 are not overlapping with the opening 204v.

In this embodiment, the metallization patterns 254 include the BM0 layer and BM1 layer, arranged from bottom to top. The BM0 layer is the innermost layer closest to the second buffer structure 210, while the BM1 layer is the outermost layer. In this embodiment, the outermost metallization pattern 254 (i.e., BM1 layer) serve as the third bonding pads 256.

Referring to FIG. 7C, the second integrated circuit structure 20C shown in FIG. 7B is bonded to the first integrated circuit structure 10C. For example, the third interconnect structure 250 of the second integrated circuit structure 20C is bonded to the first interconnect structure 140 of the first integrated circuit structure 10C using hybrid bonding technology. As a result, there is a metal-to-metal bonding between the first bonding pads 146 and the third bonding pads 256, and a dielectric-to-dielectric bonding between the dielectric layer 142 and the dielectric layer 252.

In some embodiments, the second integrated circuit structure 20C is bonding to the first integrated circuit structure 10C in a front-to-back manner by wafer-on-wafer (WoW) or chip-on wafer (CoW) stacking. When the second integrated circuit structure 20C is bonded to the first integrated circuit structure 10C by CoW stacking, the second integrated circuit structure 20C is first subjected to a dicing process before the bonding process.

In this embodiment, the metallization patterns 144 in the first interconnect structure 140 are not overlapping with the opening 204v in the vertical direction.

Then, as shown in FIG. 7D, the third integrated circuit structure 30 shown in FIG. 1K is bonded to the second integrated circuit structure 20C. For example, the fourth interconnect structure 340 of the third integrated circuit structure 30 is bonded to the second interconnect structure 240 of the second integrated circuit structure 20C using hybrid bonding technology. As a result, there is a metal-to-metal bonding between the fourth bonding pads 346 and the second bonding pads 246, and a dielectric-to-dielectric bonding between the dielectric layer 342 and the dielectric layer 242.

In some embodiments, the third integrated circuit structure 30 is bonding to the second integrated circuit structure 20C in a front-to-front manner by chip-on-chip (COC), WoW or CoW stacking. When the third integrated circuit structure 20C is bonded to the second integrated circuit structure 20C by CoC or CoW stacking, the third integrated circuit structure 30 is first subjected to a dicing process before the bonding process.

Referring to FIG. 7E, the first substrate 100 is removed by gridding process and/or polishing process (e.g. a chemical mechanical polish (CMP) process). Next, the first buffer structure 110 is deposited on one side of the first semiconductor device 120 opposite to the first interconnect structure 140. In the other word, the first buffer structure 110 is on the back side of the first integrated circuit structure 10. The first buffer structure 110 extends from the first semiconductor device 120 to the first insulation structure 130. The first semiconductor device 120 and the first insulation structure 130 are located between the first buffer structure 110 and the first interconnect structure 140.

In some embodiments, the first buffer structure 110 includes a plurality of insulation layers 112, 114, 116 and a semiconductor layer 118. In some embodiments, the insulation layers 112, 114, 116 may include materials such as silicon oxide, silicon oxycarbide, silicon nitride, silicon oxynitride, silicon nitride with oxygen (O) or carbon (C) elements, metal oxide such as Al₂O₃, or a combination thereof. These layers may be formed using processes such as CVD, PVD, ALD, or other suitable methods. In some embodiments, the semiconductor layer 118 is made of silicon or the like. The insulation layers 112, 114, 116 are disposed between the semiconductor layer 118 and the first semiconductor devices 120, as well as between the semiconductor layer 118 and the first insulation structure 130.

Referring to FIG. 7F, one or more of first conductive vias 102 are formed in the first buffer structure 110, as well as at least one of first through via 104C passing through the first buffer structure 110, the first insulation structure 130, the first interconnect structure 140 and the third interconnect structure 250 is formed. For example, a patterned photoresist layer is first formed on the first buffer structure 110 through photolithography. Then, using the aforementioned patterned photoresist layer as a mask, one or more etching processes are performed to create openings that pass through the first buffer structure 110. Openings for forming the first conductive vias 102 pass through the first buffer structure 110 and expose at least a portion of the first semiconductor devices 120. Opening for forming the first through via 104C passes through the first buffer structure 110, the first insulation structure 130, the first interconnect structure 140 and the third interconnect structure 250 and expose at least a portion of the second interconnect structure 240. In some embodiments, the openings for forming the first conductive vias 102 and the opening for forming the first through via 104C are formed in the same etching process. For example, by adjusting the hole density and/or size in the aforementioned patterned photoresist layer, openings of different sizes are formed in the first buffer structure 110. The opening for forming the first through via 104C has a larger size, while the openings for forming the first conductive vias 102 have a smaller size. Subsequently, a conductive material is deposited into the openings, and then a planarization process (such as CMP process) is employed to remove the excess conductive material beyond the first buffer structure 110, thereby obtaining the first conductive vias 102 and the first through via 104C. In some embodiments, a bottom surface of the first conductive via 102 is coplanar with a bottom surface of the first through via 104C and a bottom surface of the semiconductor layer 118 of the first buffer structure 110. The thickness of the first through via 104C is larger than a thickness of the first conductive vias 102.

In some embodiments, both of a portion of the dielectric layer 252 and the first through via 104C are passing through the second buffer structure 210. The portion of the dielectric layer 252 is disposed horizontally between the first through via 104C and the second buffer structure 210.

In some embodiments, the second interconnect structure 240 is on the front side of the second integrated circuit structure 20C, and includes metallization patterns 244 and vias 245 disposed in a dielectric layer 242. In this embodiment, the metallization patterns 244 include the MD layer, M0 layer, M1 layer, and M2 layer, arranged from bottom to top. The MD layer is the innermost layer closest to the second semiconductor device 220, while the M2 layer is the outermost layer. In this embodiment, the outermost metallization pattern 244 (i.e., M2 layer) serve as the second bonding pads 246.

In some embodiments, the first through via 104C extends into the dielectric layer 242 of the second interconnect structure 240 and is connected with a metallization pattern 244 embedded in the dielectric layer 242. In some embodiments, the first through via 104C can be connected to any of the metallization patterns 244 in the second interconnect structure 240. For example, in FIG. 7F, the first through via 104C can be connected to the M1 layer in the second interconnect structure 240. The first through via 104C may extend into the second interconnect structure 240, and the depth to which the first through via 104C extends into the second interconnect structure 240 can be adjusted according to the specific requirements.

Since the first through via 104C does not require any additional connections through other metallization patterns or vias to reach the second interconnect structure 240, the SPR including the first through via 104C may have lower resistance.

Referring to FIG. 7G, a redistribution structure 150 is formed on the first buffer structure 110 of the first integrated circuit structure 10C. The redistribution structure 150 includes dielectric structure 152 and metallization patterns 154 (sometimes referred to as redistribution layers or redistribution lines) among the dielectric structure 152. For example, the redistribution structure 150 may include a plurality of metallization patterns 154 separated from each other by the dielectric structure 152. The dielectric structure 152 may comprise multiple layers. In some embodiments, the redistribution structure 150 includes multiple vias 155, which are used to connect metallization patterns 154 located in different layers. In some embodiments, the redistribution structure 150 includes a backside signal routing, power/ground routing, or the combination thereof, or the like.

In some embodiments, the redistribution structure 150 is electrically connected to the first semiconductor devices 120 through the first conductive via 102, and electrically connected to the second interconnect structure 240 through the first through via 104C.

The bonding pads 162 and the conductive connectors 164 may be disposed on the redistribution structure 150. In some embodiments, the bonding pads 162 may be under bump metallization (UBM) pads for mounting conductive connectors 164, such as metal pillars, microbumps or the like. The bonding pads 162 may include a metal or a metal alloy. The bonding pads 162 may include aluminum, copper, nickel, an alloy thereof, or the like, for example. Other suitable pad materials may be within the contemplated scope of disclosure.

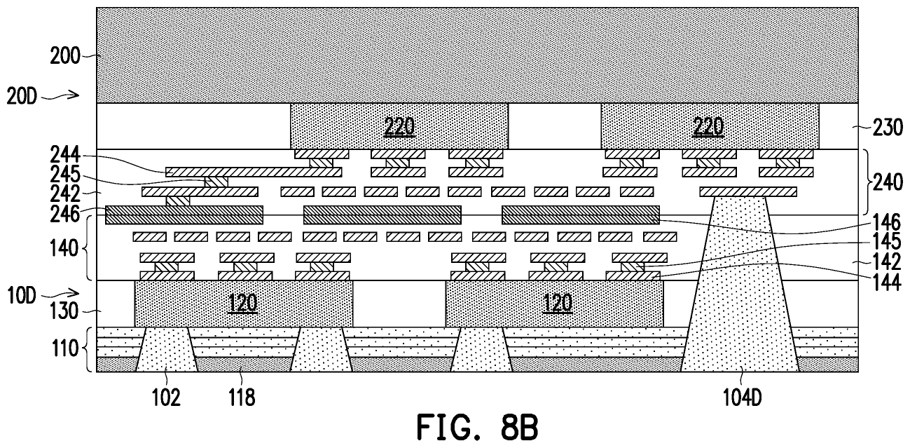

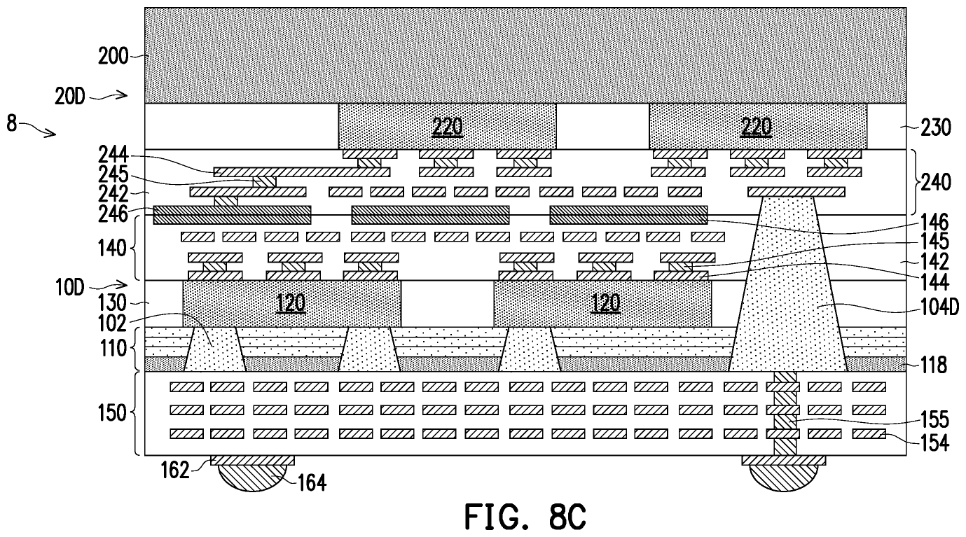

FIGS. 8A to 8C illustrate cross-sectional views of a method for fabricating a three-dimensional integrated circuit stack 8, according to various embodiments of the present disclosure. Referring to FIG. 8A, a second integrated circuit structure 20D is bonded to a first integrated circuit structure 10D. In some embodiments, the second integrated circuit structure 20D includes a second substrate 200, a second semiconductor devices 220 formed on the second substrate 200, a second insulation structure 230 surrounding the second semiconductor devices 220, and a second interconnect structure 240 formed on the second semiconductor device 220 and the second insulation structure 230.

In some embodiments, the second substrate 200 may be optionally ground to adjust the thickness of the device. In some embodiments, the second substrate 200 can be used as a heat dissipation layer, thus retaining at least a portion of the second substrate 200 can improve the thermal budget issue of the subsequently formed three-dimensional integrated circuit stack.

In some embodiments, the second interconnect structure 240 of the second integrated circuit structure 20D is bonded to the first interconnect structure 140 of the first integrated circuit structure 10D using hybrid bonding technology. As a result, there is a metal-to-metal bonding between the first bonding pads 146 and the second bonding pads 246, and a dielectric-to-dielectric bonding between the dielectric layer 142 and the dielectric layer 242.

Referring to FIG. 8B, one or more of first conductive vias 102 are formed in the first buffer structure 110, as well as at least one of first through via 104D passing through the first buffer structure 110, the first insulation structure 130 and the first interconnect structure 140 is formed. The first through via 104D may extend into the second interconnect structure 240. For example, a patterned photoresist layer is first formed on the first buffer structure 110 through photolithography. Then, using the aforementioned patterned photoresist layer as a mask, one or more etching processes are performed to create openings that pass through the first buffer structure 110. Openings for forming the first conductive vias 102 pass through the first buffer structure 110 and expose at least a portion of the first semiconductor devices 120. Opening for forming the first through via 104D passes through first buffer structure 110, the first insulation structure 130 and the first interconnect structure 140 and expose at least a portion of the second interconnect structure 240. In some embodiments, the openings for forming the first conductive vias 102 and the opening for forming the first through via 104D are formed in the same etching process. For example, by adjusting the hole density and/or size in the aforementioned patterned photoresist layer, openings of different sizes are formed in the first buffer structure 110. The opening for forming the first through via 104D has a larger size, while the openings for forming the first conductive vias 102 have a smaller size. Subsequently, a conductive material is deposited into the openings, and then a planarization process (such as CMP process) is employed to remove the excess conductive material beyond the first buffer structure 110, thereby obtaining the first conductive vias 102 and the first through via 104D. In some embodiments, a bottom surface of the first conductive via 102 is coplanar with a bottom surface of the first through via 104D and a bottom surface of the semiconductor layer 118 of the first buffer structure 110. The thickness of the first through via 104D is larger than a thickness of the first conductive vias 102.

Since the first through via 104D does not require any additional connections through other metallization patterns or vias to reach the second interconnect structure 240, the SPR including the first through via 104D may have lower resistance.

Referring to FIG. 8C, a redistribution structure 150 is formed on the first buffer structure 110 of the first integrated circuit structure 10. The redistribution structure 150 includes dielectric structure 152 and metallization patterns 154 (sometimes referred to as redistribution layers or redistribution lines) among the dielectric structure 152. For example, the redistribution structure 150 may include a plurality of metallization patterns 154 separated from each other by the dielectric structure 152. The dielectric structure 152 may comprise multiple layers. In some embodiments, the redistribution structure 150 includes multiple vias 155, which are used to connect metallization patterns 154 located in different layers. In some embodiments, the redistribution structure 150 includes a backside signal routing, power/ground routing, or the combination thereof, or the like.

In some embodiments, the redistribution structure 150 is electrically connected to the first semiconductor devices 120 through the first conductive via 102, and electrically connected to the second interconnect structure 240 through the first through via 104D.

The bonding pads 162 and the conductive connectors 164 may be disposed on the redistribution structure 150. In some embodiments, the bonding pads 162 may be under bump metallization (UBM) pads for mounting conductive connectors 164, such as metal pillars, microbumps or the like. The bonding pads 162 may include a metal or a metal alloy. The bonding pads 162 may include aluminum, copper, nickel, an alloy thereof, or the like, for example. Other suitable pad materials may be within the contemplated scope of disclosure.

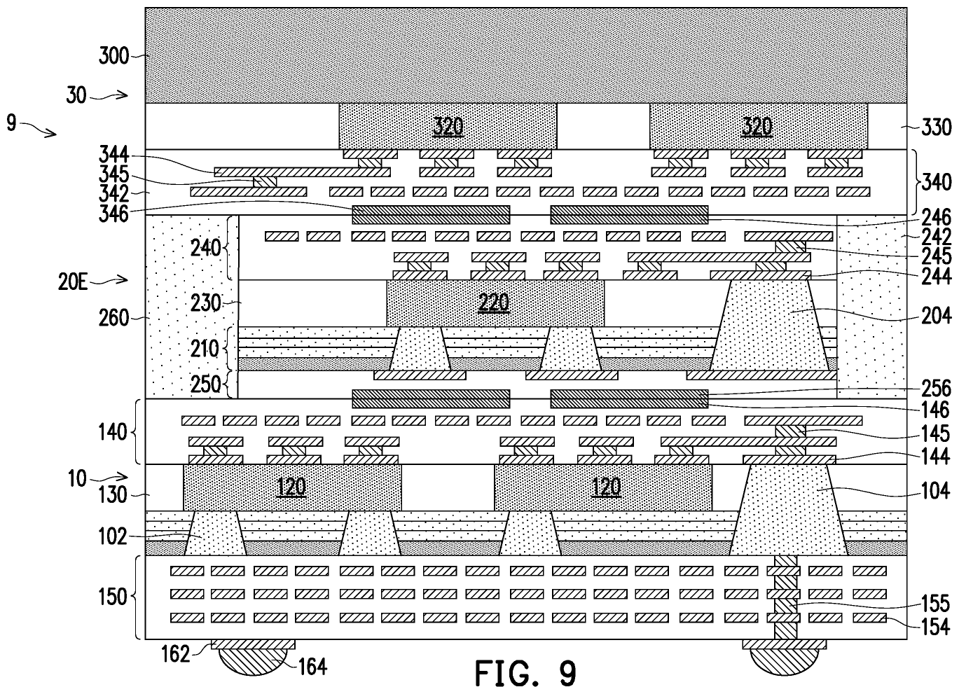

FIG. 9 illustrates a cross-sectional view of a three-dimensional integrated circuit stack 9, in accordance with some alternative embodiments. The difference between the three-dimensional integrated circuit stack 9 in FIG. 9 and the three-dimensional integrated circuit stack 1 in FIG. 1R is that: in the three-dimensional integrated circuit stack 9, an encapsulation layer 260 surrounding the third interconnect structure 250, the second buffer structure 210, the second insulation structure 230 and the second interconnect structure 240. In this embodiment, the second integrated circuit structure 20E is bonding to the first integrated circuit structure 10 in a front-to-back manner by CoW stacking. The encapsulation layer 260 is formed on the first integrated circuit structure 10 to encapsulate the second integrated circuit structure 20E on the first integrated circuit structure 10.

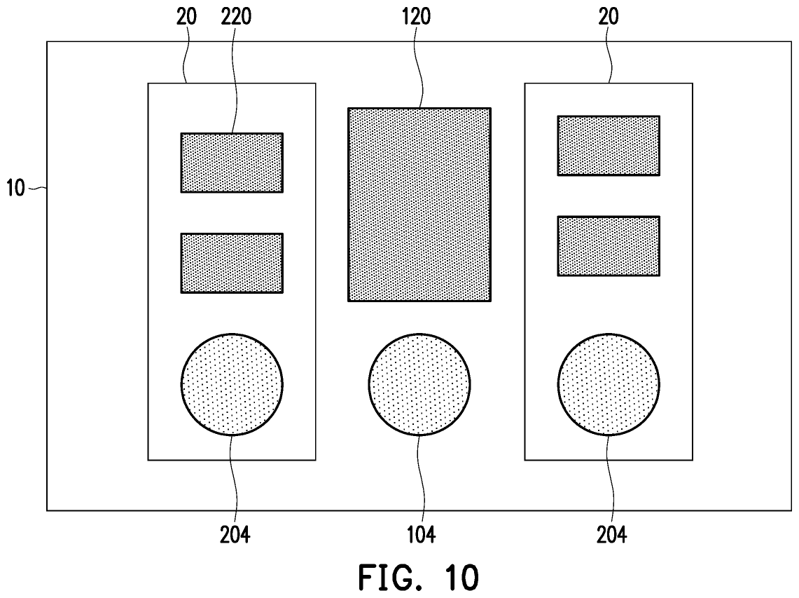

FIG. 10 illustrates a top view of a three-dimensional integrated circuit stack, in accordance with some alternative embodiments. In this embodiment, two second integrated circuit structures 20 are bonded to a single first integrated circuit structure 10. The second through via 204 of the second integrated circuit structure 20 and the first through via 104 of the first integrated circuit structure 10 can either overlap or not overlap with each other.

In some embodiments, one or more the third integrated circuit structure (not shown in FIG. 1O) may be bonded onto one or more of the second integrated circuit structures 20. The quantity of second integrated circuit structures 20 and third integrated circuit structures can be adjusted according to actual needs.

According to some embodiments of the present disclosure, a three-dimensional integrated circuit stack comprises a first integrated circuit structure, a second integrated circuit structure and a redistribution structure. The first integrated circuit structure comprises a first semiconductor device, a first buffer structure, a first interconnect structure, a first conductive via and a first through via. The first semiconductor device is located between the first buffer structure and the first interconnect structure. The first conductive via is extending through the first buffer structure and in contact with the first semiconductor device. The first through via is extending from the first buffer structure to the first interconnect structure. The second integrated circuit structure is bonding to the first integrated circuit structure. The redistribution structure is disposed on the first buffer structure, electrically connected to the first semiconductor device through the first conductive via, and electrically connected to the first interconnect structure through the first through via.

According to some embodiments of the present disclosure, a three-dimensional integrated circuit stack comprises a first die, a second die bonding to the first die, and a redistribution structure. The first die comprises a first semiconductor device, a first insulation structure adjacent to the first semiconductor, a first buffer structure, a first interconnect structure, a first conductive via and a first through via. The first semiconductor device and the first insulation structure are located between the first buffer structure and the first interconnect structure. The first conductive via is continuously passing through the first buffer structure and is electrically connected with the first semiconductor device. The first through via is continuously passing through the first buffer structure and the first insulation structure, and the first through via is electrically connected with the first interconnect structure. The redistribution structure is disposed under the first buffer structure, and electrically connected to the first conductive via and the first through via.

According to some embodiments of the present disclosure, a three-dimensional integrated circuit stack comprises a first integrated circuit structure, a second integrated circuit structure and a redistribution structure. The first integrated circuit structure comprises a first semiconductor device, a first buffer structure, a first interconnect structure, a first conductive via and a first through via. The first buffer structure is disposed under the first semiconductor device. The first interconnect structure is disposed above the first semiconductor device. The first conductive via is extending through the first buffer structure and in contact with a source/drain region of the first semiconductor device at a bottom surface of the first semiconductor device. The first through via is extending through the first buffer structure. The second integrated circuit structure is attached to the first interconnect structure. The redistribution structure is disposed under the first integrated circuit structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A three-dimensional integrated circuit stack, comprising:
a first integrated circuit structure, comprising:
a first semiconductor device;
a first buffer structure;
a first interconnect structure, wherein the first semiconductor device is located between the first buffer structure and the first interconnect structure;
a first conductive via, extending through the first buffer structure and in contact with the first semiconductor device; and
a first through via, extending from the first buffer structure to the first interconnect structure; and
a second integrated circuit structure, bonding to the first integrated circuit structure; and
a redistribution structure, disposed on the first buffer structure, electrically connected to the first semiconductor device through the first conductive via, and electrically connected to the first interconnect structure through the first through via.

2. The three-dimensional integrated circuit stack of claim 1, wherein the second integrated circuit structure comprises:
a second semiconductor device;
a second buffer structure;
a second interconnect structure, wherein the second semiconductor device is located between the second buffer structure and the second interconnect structure;
a third interconnect structure, disposed on the second buffer structure and bonding with the first interconnect structure;
a second conductive via, extending from the third interconnect structure to the second semiconductor device through the second buffer structure; and
a second through via, extending from the third interconnect structure to the second interconnect structure through the second buffer structure.

3. The three-dimensional integrated circuit stack of claim 2, further comprising a third integrated circuit structure, wherein the third integrated circuit structure comprises:
a substrate;
a third semiconductor device;
a fourth interconnect structure, wherein the third semiconductor device is disposed between the substrate and the fourth interconnect structure, and the fourth interconnect structure is bonding with the second interconnect structure.

4. The three-dimensional integrated circuit stack of claim 1, wherein a surface of the first conductive via is coplanar with a surface of the first through via.

5. The three-dimensional integrated circuit stack of claim 1, wherein the second integrated circuit structure comprises:
a second semiconductor device;
a second buffer structure;
a second interconnect structure, bonding with the first interconnect structure, wherein the second semiconductor device is located between the second buffer structure and the second interconnect structure;
a third interconnect structure, disposed on the second buffer structure;
a second conductive via, extending from the third interconnect structure to the second semiconductor device through the second buffer structure; and
a second through via, extending from the third interconnect structure to the second interconnect structure through the second buffer structure.

6. The three-dimensional integrated circuit stack of claim 1, wherein the second integrated circuit structure comprises:
a second semiconductor device;
a second buffer structure;
a second interconnect structure, wherein the second semiconductor device is located between the second buffer structure and the second interconnect structure;
a third interconnect structure, disposed on the second buffer structure and wherein a bonding pad of the third interconnect structure is bonded with a bonding pad of the first interconnect structure, the third interconnect structure including a dielectric layer surrounding the bonding pad of the third interconnect structure, wherein a portion of the dielectric layer of the third interconnect structure and the first through via are passing through the second buffer structure;
a second conductive via, extending from the third interconnect structure to the second semiconductor device through the second buffer structure and the dielectric layer of the third interconnect structure.

7. The three-dimensional integrated circuit stack of claim 1, wherein the first conductive via is connected with a source/drain region of the first semiconductor device.

8. The three-dimensional integrated circuit stack of claim 1, wherein the first buffer structure comprises a silicon layer and an insulation layer, wherein the silicon layer is located between the redistribution structure and the insulation layer.

9. A three-dimensional integrated circuit stack, comprising:
a first die, comprising:
a first semiconductor device and a first insulation structure adjacent to the first semiconductor;
a first buffer structure and a first interconnect structure, wherein the first semiconductor device and the first insulation structure are located between the first buffer structure and the first interconnect structure;
a first conductive via, continuously passing through the first buffer structure and electrically connected with the first semiconductor device; and
a first through via, continuously passing through the first buffer structure and the first insulation structure, and electrically connected with the first interconnect structure; and
a second die, bonding to the first die; and
a redistribution structure, disposed under the first buffer structure, and electrically connected to the first conductive via and the first through via.

10. The three-dimensional integrated circuit stack of claim 9, wherein the second die comprises:
a second semiconductor device and a second insulation structure adjacent to the second semiconductor device;
a second buffer structure;
a second interconnect structure and a third interconnect structure, wherein the third interconnect structure is located between the second buffer structure and the first interconnect structure, and the second semiconductor device and the second insulation structure are located between the second buffer structure and the second interconnect structure;
a second conductive via, passing through the second buffer structure and connected with a source/drain region of the second semiconductor device; and
a second through via, passing through the second buffer structure and the second insulation structure, and electrically connected with the second interconnect structure and the third interconnect structure.

11. The three-dimensional integrated circuit stack of claim 10, further comprising a third die, wherein the third die comprises:
a substrate;
a third semiconductor device;
a fourth interconnect structure, wherein the third semiconductor device is disposed between the substrate and the fourth interconnect structure, and the fourth interconnect structure is bonding with the second interconnect structure.

12. The three-dimensional integrated circuit stack of claim 10, wherein a surface of the second conductive via is coplanar with a surface of the second through via.

13. The three-dimensional integrated circuit stack of claim 9, wherein a thickness of the first through via is larger than a thickness of the first conductive via.

14. A three-dimensional integrated circuit stack, comprising:
a first integrated circuit structure, comprising:
a first semiconductor device;
a first buffer structure, disposed under the first semiconductor device;
a first interconnect structure, disposed above the first semiconductor device;
a first conductive via, extending through the first buffer structure, and in contact with a source/drain region of the first semiconductor device at a bottom surface of the first semiconductor device; and
a first through via, extending through the first buffer structure; and
a second integrated circuit structure, attached to the first interconnect structure; and
a redistribution structure, disposed under the first integrated circuit structure.

15. The three-dimensional integrated circuit stack of claim 14, wherein the first integrated circuit structure further comprises:
a first insulation structure surrounding the first semiconductor device, wherein the first insulation structure and the first semiconductor device are located between the first buffer structure and the first interconnect structure, and the first through via is passing through the first buffer structure and the first insulation structure.

16. The three-dimensional integrated circuit stack of claim 14, wherein the second integrated circuit structure comprises:
a second semiconductor device;
a second buffer structure, disposed on a first side of the second semiconductor device;
a second interconnect structure, disposed on a second side of the second semiconductor device;
a third interconnect structure, disposed on the second buffer structure, wherein a bonding pad of the first interconnect structure is attached to a bonding pad of the third interconnect structure;
a second conductive via, extending from a first side of the second buffer structure to the first side of the second semiconductor device; and
a second through via, extending from the first side of the second buffer structure to the second interconnect structure through the second buffer structure.

17. The three-dimensional integrated circuit stack of claim 16, wherein a thickness of the second through via is larger than a thickness of the second conductive via.

18. The three-dimensional integrated circuit stack of claim 14, wherein the second integrated circuit structure comprises:
a second semiconductor device;
a second buffer structure;
a second interconnect structure, bonding with the first interconnect structure, wherein the second semiconductor device is located between the second buffer structure and the second interconnect structure;
a third interconnect structure, disposed on the second buffer structure;
a second conductive via, extending from the third interconnect structure to the second semiconductor device through the second buffer structure; and
a second through via, extending from the third interconnect structure to the second interconnect structure through the second buffer structure.

19. The three-dimensional integrated circuit stack of claim 18, wherein a width of a bottom surface of the second through via facing towards the first integrated circuit structure is smaller than a width of a top surface of the second through via facing away from the first integrated circuit structure, and a width of a top surface of the first through via facing towards the second integrated circuit structure is smaller than a width of a bottom surface of the first through via facing away from the second integrated circuit structure.

20. The three-dimensional integrated circuit stack of claim 14, wherein the first through via is extending from the first buffer structure into the first interconnect structure, and is in contact with a first bonding pad of the first interconnect structure, wherein the first bonding pad is bonded with the second integrated circuit structure.
